(19) United States
(12) Patent Application Publication
(10) Pub. No.: US 2026/0255785 A1
(43) Pub. Date: Aug. 27, 2026

(54) LIGHT EMITTING ELEMENT, ELECTRONIC APPARATUS INCLUDING THE LIGHT EMITTING ELEMENT, AND METHOD FOR MANUFACTURING THE LIGHT EMITTING ELEMENT

(71) Applicant: Samsung Display Co., LTD., Yongin-si (KR)

(72) Inventors: JUNGSUB HWANG, Yongin-si (KR); MYOUNGJIN PARK, Yongin-si (KR); Jungho JO, Yongin-si (KR)

(21) Appl. No.: 19/535,075

(22) Filed: Feb. 10, 2026

(30) Foreign Application Priority Data
Feb. 21, 2025 (KR) 10-2025-0023126

(51) Int. Cl. H10K 50/15; H10K 50/115; H10K 59/12; H10K 59/35

(52) U.S. Cl. CPC H10K 50/15; H10K 50/115; H10K 59/1201; H10K 59/35

(57) ABSTRACT

Provided is a method for manufacturing a light-emitting element according to an embodiment of the inventive concept, the method includes forming a hole transport region by providing, on the first electrode, a mixture including a hole transport material and a first fluoride source including fluorine, forming an emission layer including a quantum dot on the hole transport region, forming an electron transport region on the emission layer, and forming a second electrode on the electron transport region. In the forming of the emission layer, at least a portion of the first fluoride source included in the hole transport region moves to the emission layer.

This application claims priority to Korean Patent Application No. 10-2025-0023126, filed on Feb. 21, 2025, and all the benefits accruing therefrom under 35 U.S.C. § 119, the content of which in its entirety is herein incorporated by reference.

### BACKGROUND

The present disclosure herein relates to a light-emitting element, an electronic apparatus including the light-emitting element, and a method for manufacturing the light-emitting element.

Various display devices used for multimedia apparatuses such as televisions, mobile phones, tablet computers, navigations and game consoles are being developed. In such display devices, a self-luminescent type display element in which light-emitting materials including an organic compound emit light to achieve display is used.

To improve the color reproductivity of the display device, a light-emitting element using a quantum dot as light-emitting materials is being developed, and improvements in luminous efficiency and lifespan of the light-emitting element using a quantum dot are desired.

### SUMMARY

The present disclosure provides a light-emitting element having improved luminous efficiency and element lifespan.

The present disclosure also provides an electronic apparatus having excellent display quality characteristics by including quantum dots having improved luminous characteristics.

The present disclosure also provides a method for manufacturing a light-emitting element having improved luminous efficiency and element lifespan.

An embodiment of the inventive concept provides method for manufacturing a light-emitting element including: forming a hole transport region by providing, on a first electrode, a mixture that includes a hole transport material, and a first fluoride source including fluorine; forming an emission layer including a quantum dot on the hole transport region; forming an electron transport region on the emission layer; and forming a second electrode on the electron transport region, and in the forming of the emission layer, at least a portion of the first fluoride source which is included in the hole transport region moves to the emission layer.

In an embodiment, a concentration of fluorine in the hole transport region before the forming of the emission layer is defined as a first concentration, a concentration of fluorine in the hole transport region after the forming of the emission layer is defined as a second concentration, and the second concentration may be smaller than the first concentration.

In an embodiment, the quantum dot may include a core, a shell covering the core, and fluorine ions bonded to at least one of a surface of the core or a surface of the shell.

In an embodiment, the method may further include preparing a quantum dot prior to the forming of the emission layer, and the preparing of the quantum dot may include forming the core, forming the shell, and reacting the at least one of the surface of the core or the surface of the shell with fluorine.

In an embodiment, the forming of the hole transport region may be carried out through an inkjet process.

In an embodiment, the forming of the hole transport region may include forming a preliminary hole transport region by providing, on the first electrode, the mixture that includes the hole transport material and the first fluoride source and drying or performing a heat treatment on the preliminary hole transport region.

In an embodiment, the forming of the emission layer may be carried out through an inkjet process.

In an embodiment, the forming of an emission layer may include forming a preliminary emission layer by providing a quantum dot composition including the quantum dot onto the hole transport region and drying or performing a heat treatment on the preliminary emission layer.

In an embodiment, the quantum dot composition may further include a second fluoride source.

In an embodiment, the forming of the electron transport region may include forming a preliminary electron transport region by providing, on the emission layer, an electron transport composition that includes an electron transport material, and drying or performing a heat treatment on the preliminary electron transport region.

In an embodiment, the electron transport material may include a metal oxide.

In an embodiment of the inventive concept, a light-emitting element includes a first electrode, a second electrode disposed on the first electrode, an emission layer that is disposed between the first electrode and the second electrode and includes a quantum dot, and a hole transport region that is disposed between the first electrode and the emission layer, and each of the emission layer and the hole transport region may include a first fluoride source including fluorine.

In an embodiment, the hole transport region includes a hole injection layer disposed on the first electrode, and a hole transport layer disposed on the hole injection layer and contacting the emission layer, and the hole transport layer includes the first fluoride source.

In an embodiment, the quantum dot may include a core and a shell covering the core.

In an embodiment, the quantum dot may further include fluorine ions bonded to at least one of a surface of the core or a surface of the shell.

In an embodiment, the quantum dot may further include a ligand bonded to at least one of a surface of the core or a surface of the shell.

In an embodiment, the light-emitting element may further include an electron transport region disposed between the second electrode and the emission layer, and including a metal oxide.

In an embodiment of the inventive concept, an electronic apparatus includes a display module that includes a display panel, and an input sensor disposed on the display panel, and a power source module supplying power to the display module, wherein the display panel includes a circuit layer, and a display element layer disposed on the circuit layer and including a pixel-defining film in which a light-emitting element and a pixel opening are defined, and the light-emitting element includes a first electrode, a second electrode disposed on the first electrode, an emission layer disposed between the first electrode and the second electrode, and including a quantum dot, and a hole transport region disposed between the first electrode and the emission layer, wherein each of the emission layer and the hole transport region includes a fluoride source including fluorine.

In an embodiment, a fluorine concentration in the emission layer, measured before applying a voltage to the light-emitting element is set as a reference concentration, a concentration of fluorine in the emission layer after applying a voltage to the light-emitting element may gradually increase from the reference concentration.

In an embodiment, the light-emitting element may include a first light-emitting element including a first emission layer that is which emits blue light, a second light-emitting element including a second emission layer that is which emits green light, and a third light-emitting element including a third emission layer that is which emits red light, and at least one among the first emission layer, the second emission layer, or the third emission layer may include the quantum dot and the first fluoride source.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of an electronic apparatus according to an embodiment;

FIG. 2 illustrate schematic views of electronic apparatuses according to embodiments;

FIG. 3 is a perspective view of a display module according to an embodiment of the inventive concept;

FIG. 4 is a cross-sectional view of the display module according to an embodiment of the inventive concept, taken along line I-I′ in FIG. 3;

FIG. 5 is a plan view of a display module according to an embodiment of the inventive concept;

FIG. 6 is a cross-sectional view of a display module according to an embodiment of the inventive concept;

FIG. 7A is a cross-sectional view of a light-emitting element according to an embodiment of the inventive concept;

FIG. 7B is a cross-sectional view illustrating some components of a light-emitting element according to an embodiment of the inventive concept;

FIG. 8 is a cross-sectional view of a light-emitting element according to an embodiment of the inventive concept;

FIG. 9 is a flow chart illustrating a method for manufacturing a light-emitting element according to an embodiment of the inventive concept;

FIG. 10A to FIG. 10I are views schematically illustrating some steps among steps of a method for manufacturing a light-emitting element according to an embodiment of the inventive concept;

FIG. 11A is a view schematically illustrating changes, over time, of a quantum dot included in a light-emitting element according to Example; and

FIG. 11B is a view schematically illustrating changes, over time, of a quantum dot included in a light-emitting element according to a Comparative Example.

### DETAILED DESCRIPTION

In the inventive concept, various modifications may be made, various forms may be applied, and specific embodiments will be illustrated in the drawings and described in detail in the text. However, this is not intended to limit the inventive concept to a specific disclosure form, and it should be understood to include all changes, equivalents, and substitutes included in the spirit and scope of the inventive concept.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

In this specification, “directly disposed” may mean that there is no additional layer, film, region, substrate, or the like existing between one part of a layer, film, region, substrate, or the like and another part. For example, “directly disposed” may refer to being disposed between two layers or two members without using an additional member such as an adhesion member.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, and the like may be used herein to describe various elements, the elements are not to be limited by these terms. These terms are used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions “a”, “an” and “the” are intended to include the plural forms as well, unless the context clearly indicates otherwise.

In some aspects, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

In the present specification, the term “substituted or unsubstituted” may refer to being substituted or unsubstituted with at least one substituent selected from the group consisting of a deuterium atom, a halogen atom, a cyano group, a nitro group, an amino group, a silyl group, an oxy group, a thio group, an amine group, a sulfinyl group, a sulfonyl group, a carbonyl group, a boron group, a phosphine group, a phosphine oxide group, a phosphine sulfide group, an alkyl group, an alkenyl group, an alkynyl group, a hydrocarbon ring group, an aryl group, and a heterocyclic group. In some aspects, each of the example substituents may be substituted or unsubstituted. For example, a biphenyl group may be interpreted as an aryl group, and may also be interpreted as a phenyl group substituted with a phenyl group.

As used herein, examples of a halogen atom include a fluorine atom, a chlorine atom, a bromine atom, or an iodine atom.

As used herein, an alkyl group may be a linear chain, a branched chain, or a ring. The carbon number of the alkyl group may be 1 to 60, 1 to 50, 1 to 30, 1 to 20, 1 to 10, or 1 to 6. Examples of the alkyl group may include a methyl group, an ethyl group, an isopropyl group, an n-butyl group, an s-butyl group, a t-butyl group, an i-butyl group, a 2-ethylbutyl group, a 3,3-dimethylbutyl group, an n-pentyl group, an i-pentyl, a neopentyl group, a t-pentyl group, an 1-methylpentyl group, a 3-methylpentyl group, a 2-ethylpentyl group, a 4-methyl-2-pentyl group, an n-hexyl group, an 1-methylhexyl group, a 2-ethylhexyl group, a 2-butylhexyl group, an n-heptyl group, an 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-a hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, an 1-adamantyl group, a 2-adamantyl group, an isobornyl group, a bicycloheptyl group, and the like, but embodiments of the present disclosure are not limited thereto.

In the present specification, an alkenyl group means a hydrocarbon group including one or more carbon double bonds in the middle or at the terminal of an alkyl group having 2 or more carbon atoms. The alkenyl group may be a linear, or branched chain. The carbon number is not particularly limited, but the carbon number may be 2 to 60, 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, and the like, but are not limited thereto.

In the present specification, an alkynyl group means a hydrocarbon group including one or more carbon double bonds in the middle or at the terminal of an alkyl group having 2 or more carbon atoms. The alkynyl group may be a linear, or branched chain. The carbon number is not particularly limited, but the carbon number may be 2 to 30, 2 to 20, or 2 to 10. Specific examples of the alkynyl group may include an ethynyl group, a propynyl group, and the like, but are not limited thereto.

In the present specification, a hydrocarbon ring group means an optional functional group or substituent derived from an aliphatic hydrocarbon ring. The hydrocarbon ring group may be a saturated hydrocarbon ring group having 5 to 20 ring-forming carbon atoms.

In the present specification, an aryl group means an optional functional group or substituent derived from an aromatic hydrocarbon ring. The aryl group may be a monocyclic aryl group, or polycyclic aryl group. The ring-forming carbon number of the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and the like, but are not limited thereto.

In the present specification, a heterocyclic group means an optional functional group or substituent derived from a ring including one or more among B, O, N, P, Si, and S as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

As used herein, a heterocyclic group may include one or more among B, O, N, P, Si, Se and S as hetero atoms. If the heterocyclic group includes two or more heteroatoms, the two or more heteroatoms may be the same as or different from each other. The heterocyclic group may be a monocyclic heterocyclic group or a polycyclic heterocyclic group, and has the concept including a heteroaryl group. The number of ring-forming carbon atoms in the heterocyclic group may be 2 to 60, 2 to 30, 2 to 20, or 2 to 10.

In the present specification, an aliphatic heterocyclic group may include one or more among B, O, N, P, Si, Se and S as heteroatoms. The number of ring-forming carbon atoms in the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and the like, but are not limited thereto.

In the present specification, a heteroaryl group may include one or more among B, O, N, P, Si, Se and S as heteroatoms. If the heteroaryl group includes two or more heteroatoms, the two or more heteroatoms may be the same as or different from each other. The heteroaryl group may be a monocyclic heterocyclic group, or polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and the like, but are not limited thereto.

In the present specification, a silyl group includes an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but are not limited thereto.

In the present specification, the carbon number of a carbonyl group is not specifically limited, but the carbon number may be 1 to 40, 1 to 30, or 1 to 20. For example, the carbonyl group may have a structure below but is not limited thereto.

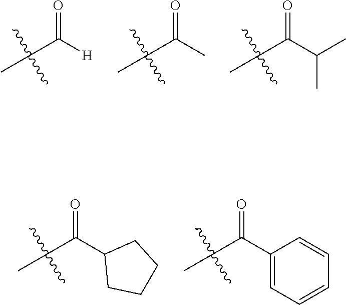

In the present specification, the carbon number of a sulfinyl group and sulfonyl group is not specifically limited but may be 1 to 30. The sulfinyl group may include an alkyl sulfinyl group and an aryl sulfinyl group. The sulfonyl group may include an alkyl sulfonyl group and an aryl sulfonyl group.

In the present specification, a thio group may include an alkyl thio group, and an aryl thio group. The thio group may mean a group in which a sulfur atom is bonded to the above-defined alkyl group or aryl group. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and the like, but are not limited thereto.

In the present specification, an oxy group may mean a group in which an oxygen atom is bonded to the above-defined alkyl group or aryl group. The oxy group may include an alkoxy group and an aryl oxy group. The alkoxy group may be a linear, branched or cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and the like, but are not limited thereto.

In the present specification, a boron group may mean a group in which a boron atom is bonded to the above-defined alkyl group or aryl group. The boron group includes an alkyl boron group and an aryl boron group. Examples of the boron group include a dimethylboron group, a diethylboron group, a t-butylmethylboron group, a diphenylboron group, a phenylboron group, and the like, but are not limited thereto.

In the present specification, the carbon number of an amine group is not specifically limited but may be 1 to 30. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, and the like, but are not limited thereto.

In the present specification, the alkyl group in an alkylthio group, an alkylsulfoxy group, an alkylaryl group, an alkylamino group, an alkylboron group, an alkyl silyl group, and an alkyl amine group may be the same as the examples of the above-described alkyl group.

In the present specification, the aryl group in an aryloxy group, an arylthio group, an arylsulfoxy group, an aryl amino group, an arylboron group, an aryl silyl group, an aryl amine group may be the same as the examples of the above-described aryl group.

As used herein, acyl halide may refer to a substituent having a “—C(═O)R” structure. Herein, R is a halogen atom. That is, R is F, Cl, Br, or I.

As used herein, a hydroxy group may refer to a substituent having a “—OH” structure.

As used herein, a thiol group may refer to a substituent having a “—SH” structure.

As used herein, a phosphine group may include an alkyl phosphine group, and an aryl phosphine group. The phosphine group may mean a group in which a phosphorus atom is bonded to the above-defined alkyl group or aryl group. Examples of a phosphine group may include a methylphosphine group, an ethylphosphine group, a propylphosphine group, a butylphosphine group, a penthylphosphine group, a hexylphosphine group, an octylphosphine group, a cyclopentylphosphine group, a cyclohexylphosphine group, a phenylphosphine group, a diphenylphosphine group, a triphenylphosphine group, and the like, but are not limited thereto.

As used herein, a carboxy group may refer to a substituent having a “—COOH” structure.

As used herein, (meth)acrylate may mean acrylate and methacrylate.

Hereinafter, a light-emitting element according, an electronic apparatus including the light-emitting element, and a method for manufacturing a light-emitting element to embodiments of the inventive concept will be explained with reference to the accompanying drawings.

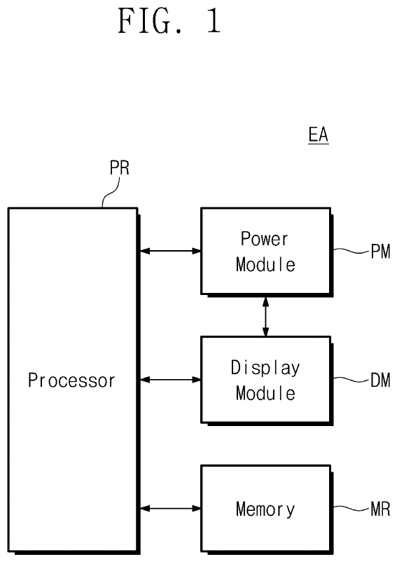

FIG. 1 is a block diagram of an electronic apparatus according to an embodiment. Referring to FIG. 1, an electronic apparatus EA according to an embodiment may include a display module DM, a processor PR, memory MR, and a power module PM.

The processor PR may include at least one among a central processing unit (CPU), an application processor (AP), a graphic processing unit (GPU), a communication processor (CP), an image signal processor (ISP), and a controller.

In the memory MR, data information for an operation of the processor PR or the display module DM may be stored. In an example in which the processor PR executes an application stored in the memory MR, a video data signal and/or input control signal may be transmitted to the display module DM, and the display module DM may process the provided signal to output video information through a display screen. The display module DM may include a display panel displaying a video.

The power module PM may include a power supply module such as a power adapter or battery device, and a power conversion module that converts power supplied by the power supply module to generate power for operations of the electronic apparatus EA.

At least one among the above-described components of the electronic apparatus EA may be included in a display module according to embodiments and a display device according to an embodiment including the same, which will be described later. In some aspects, some individual modules functionally included in one module may be included in the display device, and some other modules may be provided separately from the display device. For example, the display device may include the display module DM, and the processor PR, the memory MR, and the power module PM may be provided in other device forms in the electronic apparatus EA other than the display device.

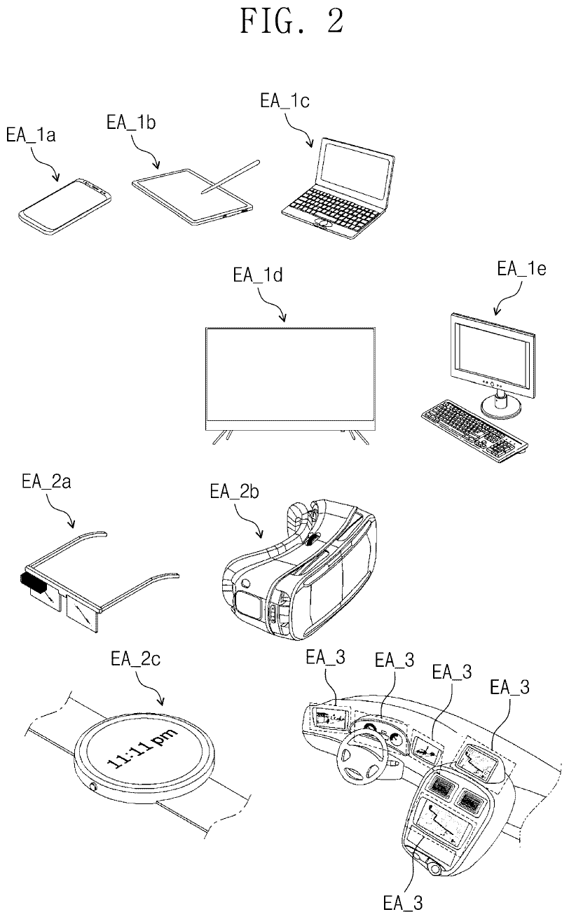

FIG. 2 illustrate schematic views of various electronic apparatuses according to embodiments.

Referring to FIG. 2, various electronic apparatuses including the display module according to an embodiment may not include only an image-displaying electronic apparatus such as a smart phone EA_1a, a tablet PC EA_1b, a laptop computer EA_1c, a TV EA_1d, and a desktop monitor EA_1e, but also include an wearable electronic apparatus such as smart glasses EA_2a, a head mounted display EA_2b, or a smart watch EA_2c, and a vehicular electronic apparatus EA_3 such as a center information display (CID) located on a vehicle's instrument cluster, center fascia, or dashboard, and a room mirror display etc.

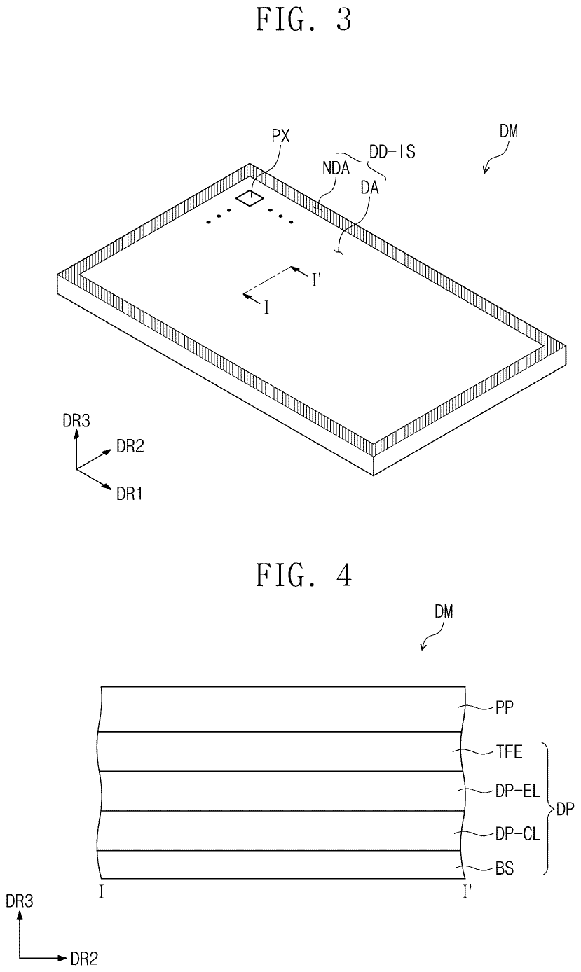

FIG. 3 is a perspective view of a display module according to an embodiment of the inventive concept. FIG. 4 is a cross-sectional view of a display module DM according to an embodiment of the inventive concept, taken along line I-I′ in FIG. 3.

The display module DM may display an image (or a video) through a display surface DD-IS. The display surface DD-IS may be parallel to a plane defined by a first direction DR1 and a second direction DR2. The display surface DD-IS may include a display region DA and a non-display region NDA.

A pixel PX may be disposed in the display region DA, and no pixel PX may be disposed in the non-display region NDA. The non-display region NDA may be defined along an edge of the display surface DD-IS. The non-display region NDA may surround the display region DA. However, embodiments of the present disclosure are not limited thereto, and the non-display region NDA may be omitted, or may be disposed at a single side of the display region DA.

FIG. 3 illustrates the display module DM equipped with a flat display surface DD-IS, but embodiments of the present disclosure are not limited thereto. The display module DM may include a curved display surface or a 3-dimensional display surface.

The 3-dimensional display surface may include a plurality of display regions indicating different directions.

In FIG. 3 and the following drawings, the first direction DR1 to the third direction DR3 are illustrated. Directions indicated by the first to third directions DR1, DR2, and DR3 described in the present specification are relative concepts and may thus be changed to other directions. In the present specification, the first direction DR1 and the second direction DR2 may be perpendicular to each other, and the third direction DR3 is in a normal direction of a plane defined by the first direction DR1 and the second direction DR2. In the present specification, a ‘plane’ refers to a plane defined by the first direction DR1 and the second direction DR2, and a ‘cross-section’ refers to a surface that is perpendicular to the plane defined by the first direction DR1 and the second direction DR2, and is parallel to the third direction DR3. A thickness direction of the display module DM may be parallel to the third direction DR3, which is a normal direction of a plane defined by the first direction DR1 and the second direction DR2.

In the present specification, a top surface (or front surface), and a bottom surface (or rear surface) of each member constituting the display module DM may be defined based on the third direction DR3. More specifically, among two surfaces, of one member, which face each other in the third direction DR3, a surface relatively adjacent to the display surface DD-IS may be defined as a front surface (or top surface), and a surface relatively far from the display surface DD-IS may be defined as a rear surface (or bottom surface). In some aspects, in the present specification, an upper part (or upper side) and a lower part (or lower side) may be defined based on the third direction DR3, the upper part (or upper side) may be defined based on a direction getting closer to the display surface DD-IS, and the lower part (or lower side) may be defined based on a direction getting farther from the display surface DD-IS.

In the present specification, the wording, one component being “directly disposed/directly formed” on another component means that there is no third component between the one component and the other component. That is, the wording, one component being “directly disposed/directly formed” on another component means that the one component is in “contact” with the other component.

FIG. 4 is a cross-sectional view illustrating a portion taken along line I-I′ in FIG. 3. FIG. 4 may be a cross-sectional view of a display module DM according to an embodiment.

The display module DM may include a display panel DP and an optical member PP disposed on the display panel DP. The display panel DP may include a base substrate BS, a circuit layer DP-CL disposed on the base layer BS, a display element layer DP-EL disposed on the circuit layer DP-CL, and an encapsulation layer TFE disposed on the display element layer DP-EL.

The display panel DP may be a component that substantially generates a video. The display panel DP may be a light-emitting display panel. For example, the display panel DP may be a quantum dot light-emitting display panel including a quantum dot light-emitting element.

The base substrate BS may be a member providing a base surface on which the circuit layer DP-CL is disposed. The base substrate BS may be a rigid substrate or a flexible substrate that is bendable, foldable, rollable, and the like. The base substrate BS may be a glass substrate, a metal substrate, a polymer substrate, or the like. However, embodiments of the present disclosure are not limited thereto, and the base substrate BS may be an inorganic layer, an organic layer, or a composite material layer.

The circuit layer DP-CL may be disposed on the base substrate BS. The circuit layer DP-CL may include an insulating layer, a semiconductor pattern, a conductive pattern, a signal line, and the like. After an insulating layer, a semiconductor layer, and a conductive layer are formed on the base substrate BS through coating, deposition or the like, the insulating layer, the semiconductor layer, and the conductive layer may be selectively patterned by performing a photolithography process multiple times. Thereafter, the semiconductor pattern, the conductive pattern, and the signal line included in the circuit layer DP-CL may be formed.

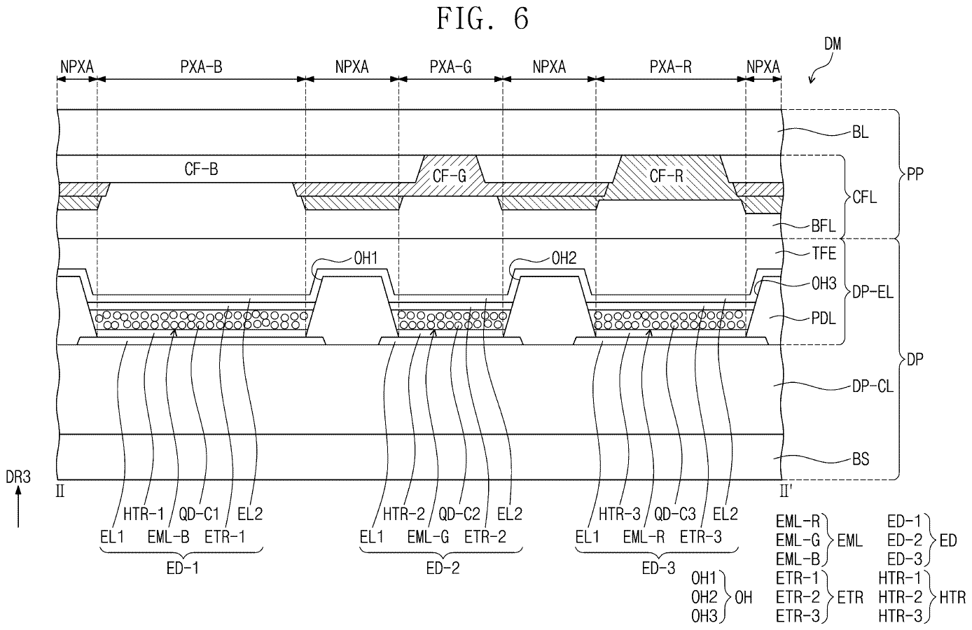

The display element layer DP-EL may be disposed on the circuit layer DP-CL. The display element layer DP-EL may include a pixel-defining film PDL (FIG. 6) and first to third light-emitting elements ED-1, ED-2, and ED-3 (FIG. 6), which will be described later. For example, the display element layer DP-EL may include an organic light-emitting material, an inorganic light-emitting material, an organic-inorganic light-emitting material, quantum dots, quantum rods, a micro-LED, or a nano-LED. More specifically, the display element layer DP-EL may include quantum dots.

The encapsulation layer TFE may protect the display element layer DP-EL from moisture, oxygen, and a foreign substance such as dust particles. The encapsulation layer TFE may include at least one inorganic layer. The encapsulation layer TFE may include a structure in which an inorganic layer, an organic layer, and an inorganic layer are sequentially stacked.

The optical member PP may be disposed on the display panel DP, and control the reflected light of external light at the display panel DP. The optical member PP may include, for example, a polarization layer (not illustrated), or a color filter layer CFL (FIG. 6). Additional or alternative to the example illustrated in the drawings, the optical member PP may be omitted.

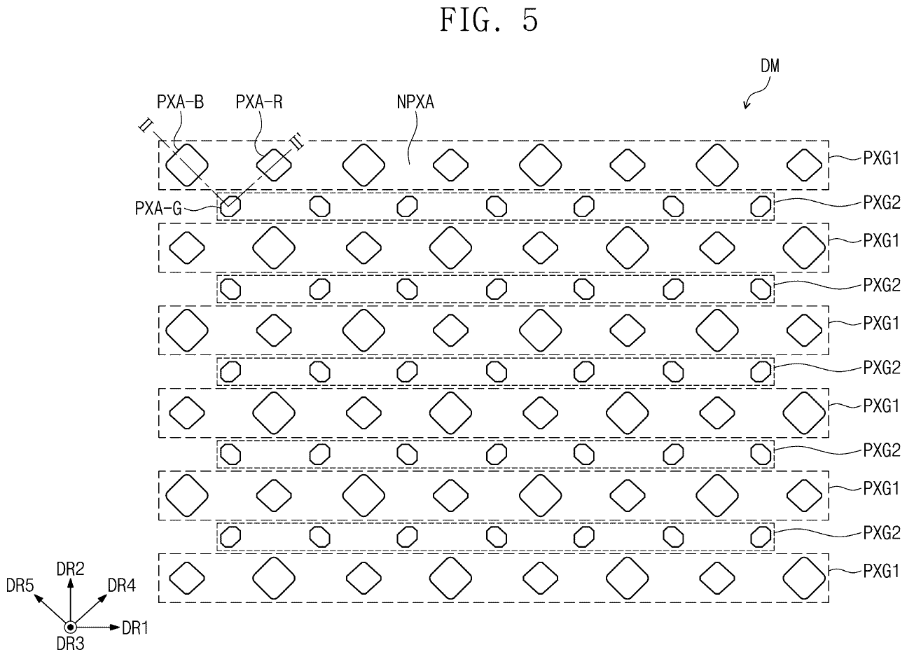

FIG. 5 is a plan view illustrating a display module according to an embodiment. FIG. 6 is a cross-sectional view of a display module according to an embodiment. FIG. 6 is a cross-sectional view illustrating a portion taken along line II-II′ in FIG. 5.

Referring to FIG. 5 and FIG. 6, the display module DM according to an embodiment includes a plurality of light-emitting elements ED-1, ED-2, and ED-3. In some aspects, the display module DM according to an embodiment may include a display panel DP that includes the plurality of light-emitting elements ED-1, ED-2, and ED-3, and the optical member PP disposed on the display panel DP. Additional or alternative to the example illustrated in the drawings, the optical member PP may be omitted in the display module DM according to an embodiment.

The display panel DP may include a base substrate BS, a circuit layer DP-CL provided on the base substrate BS, and a display element layer DP-EL, and the display element layer DP-EL may include a pixel-defining film PDL, light-emitting elements ED-1, ED-2, and ED-3 disposed between pixel-defining films PDL and an encapsulation layer TFE disposed on the light-emitting elements ED-1, ED-2, and ED-3.

In FIG. 6, the base substrate BS may include a single-layered, or a multi-layered structure. For example, the base substrate BS may include a first synthetic resin layer, an intermediate layer having a multi-layered or single-layered structure, and a second synthetic resin layer. The intermediate layer may be referred to as a base barrier layer. The intermediate layer may include a silicon oxide (SiOₓ) layer and an amorphous silicon (a-Si) layer disposed on the silicon oxide layer but is not particularly limited thereto. For example, the intermediate layer may include at least one of a silicon oxide layer, a silicon nitride layer, a silicon oxynitride layer, or an amorphous silicon layer.

Each of the first and second synthetic resin layers may include a polyimide-based resin. In some aspects, each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. As used herein, a “α”-based resin means including an “α” functional group.

The circuit layer DP-CL may be disposed on the base substrate BS and include a plurality of transistors (not illustrated). The transistors (not illustrated) may each include a control electrode, an input electrode, and an output electrode. For example, the circuit layer DP-CL may include a switching transistor, and a driving transistor for driving the light-emitting elements ED-1, ED-2, and ED-3 of the display element layer DP-EL.

Emission regions PXA-R, PXA-G, and PXA-B may be divided into a plurality of groups according to colors of light generated from the light-emitting elements ED-1, ED-2, and ED-3. FIG. 5 and FIG. 6 illustrate three emission regions XA-R, PXA-G, and PXA-B emitting red light, green light, and blue light for illustrative purposes. For example, the display module DM according to an embodiment may include a red emission region PXA-R, a green emission region PXA-G, and a blue emission region PXA-B, which are separated from each other.

The display panel DP may include the plurality of light-emitting elements ED-1, ED-2, and ED-3, which emit light of different wavelength regions. The plurality of light-emitting elements ED-1, ED-2, and ED-3 may emit light having different colors. For example, the display panel DP may include a first light-emitting element ED-1 that emits blue light, a second light-emitting element ED-2 1 that emits green light, and a third light-emitting element ED-3 1 that emits red light. However, embodiments of the present disclosure are not limited thereto, and the first to third light-emitting elements ED-1, ED-2, and ED-3 may emit light of the same wavelength region, or at least one may emit light of different wavelength regions.

For example, the blue emission region PXA-B, the green emission region PXA-G, and the red emission region PXA-R of the display module DM may correspond to the first light-emitting element ED-1, the second light-emitting element ED-2, and the third light-emitting element ED-3, respectively.

The display module DM according to an embodiment may include the plurality of light-emitting elements ED-1, ED-2, and ED-3, and the light-emitting elements ED-1, ED-2, and ED-3 may respectively include emission layers EML-B, EML-G, and EML-R including quantum dots QD-C1, QD-C2, and QD-C3. In an embodiment, at least one among the first to third emission layers EML-B, EML-G, and EML-R included in the light-emitting elements ED-1, ED-2, and ED-3 may include the quantum dots QD-C1, QD-C2 or QD-C3. For example, at least one among the first emission layer EML-B included in the first light-emitting element ED-1, the second emission layer EML-G included in the second light-emitting element ED-2, and the third emission layer EML-R included in the third light-emitting element ED-3 may include quantum dots QD-C1, QD-C2 or QD-C3.

The first emission layer EML-B of the first light-emitting element ED-1 may include first quantum dots QD-C1. The first quantum dots QD-C1 may emit blue light, which is first light. The second emission layer EML-G of the second light-emitting element ED-2, and the third emission layer EML-R of the third light-emitting element ED-3 may respectively include second quantum dots QD-C2 and third quantum dots QD-C3. The second quantum dots QD-C2 and the third quantum dots QD-C3 may respectively emit green light, which is second light, and red light, which is third light.

In an embodiment, the first light may have a central wavelength in a wavelength region of about 410 nm to about 480 nm, the second light may have a central wavelength in a wavelength region of about 500 nm to about 570 nm, and the third light may have a central wavelength in a wavelength region of about 625 nm to about 675 nm.

In the present specification, the quantum dots refer to crystals of a semiconductor compound. The quantum dots may emit light of various emission wavelengths depending on the crystal size. The quantum dots may emit light of various emission wavelengths by controlling an element ratio in the quantum dot compound.

The quantum dots may have a diameter of, for example, about 1 nm to about 10 nm.

The quantum dots may be synthesized through a wet chemical process, an organic metal chemical vapor deposition process, a molecular beam epitaxy process, similar processes, or the like.

The wet chemical process is a method of mixing an organic solvent and a precursor material and then growing a crystal of a quantum dot particle. In an example in which the crystal is grown, the organic solvent may naturally serve as a dispersant that is coordinated to a surface of the quantum dot crystal and may control the growth of the crystal. Therefore, the wet chemical process may control the growth of the quantum dot QD-C particles through a simpler and more cost-effective process than a vapor deposition method such as metal organic chemical vapor deposition (MOCVD) or molecular beam epitaxy (MBE).

The quantum dots QD-C1, QD-C2, and QD-C3 included in the emission layer EML may be semiconductor nanocrystals selected from among a II-VI group compound, a III-V group compound, a III-VI group compound, a I-III-VI group compound, a IV-VI group compound, a IV group element, a IV group compound, or combinations thereof.

The II-VI group compound may be selected from the group consisting of: binary compounds selected from the group consisting of CdSe, CdTe, CdS, ZnS, ZnSe, ZnTe, ZnO, HgS, HgSe, HgTe, MgSe, MgS, and a mixture thereof, ternary compounds selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof, and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The II-VI group semiconductor compound may further include a I group metal and/or a IV group element. The I-II-VI group compound may be selected from CuSnS or CuZnS, and as the II-IV-VI group compound, ZnSnS and the like may be selected. The I-II-IV-VI group compound may be selected from quaternary compounds selected from the group consisting of Cu₂ZnSnS₂, Cu₂ZnSnS₄, Cu₂ZnSnSe₄, Ag₂ZnSnS₂ or a mixture thereof.

The II-VI group compound may include: binary compounds such as In₂S₃, and In₂Se₃; ternary compounds such as InGaS₃, and InGaSe₃; or any combination thereof.

The I-III-VI group compound may be selected from ternary compounds selected from the group consisting of AgInS, AgInS₂, CuInS, CuInS₂, AgGaS₂, CuGaS₂, CuGaO₂, AgGaO₂, AgAlO₂ and a mixture thereof, or quaternary compounds such as AgInGaS₂, and CuInGaS₂.

The III-V group compound may be selected from the group consisting of: binary compounds selected from the group consisting of GaN, GaP, GaAs, GaSb, AlN, AlP, AlAs, AlSb, InN, InP, InAs, InSb, and a mixture thereof, ternary compounds selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and quaternary compounds selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The III-V group compound may further include a II group metal. For example, as the III-II-V group compound, InZnP and the like may be selected.

The IV-VI group compound may be selected from the group consisting of: binary compounds selected from the group consisting of SnS, SnSe, SnTe, PbS, PbSe, PbTe, and a mixture thereof, ternary compounds selected from the group consisting of SnSeS, SnSeTe, SnSTe, PbSeS, PbSeTe, PbSTe, SnPbS, SnPbSe, SnPbTe, and a mixture thereof, quaternary compounds selected from the group consisting of SnPbSSe, SnPbSeTe, SnPbSTe, and a mixture thereof.

An example of the JJ-IV-V group semiconductor compound may be a ternary compound selected from the group consisting of ZnSnP, ZnSnP₂, ZnSnAs₂, ZnGeP₂, ZnGeAs₂, CdSnP₂, CdGeP₂ and a mixture thereof.

The IV group element may be selected from the group consisting of Si, Ge and a mixture thereof. The IV group compound may be a binary compound selected from the group consisting of SiC, SiGe, and a mixture thereof.

Each element contained in a multicomponent compound such as the binary compound, the ternary compound, and the quaternary compound may be present in particles at a uniform concentration or non-uniform concentration. That is, the formulas above may refer to types of elements included in the compound, and element ratios in the compounds may be different. For example, AgInGaS₂ may refer to AgInₓGab₁₋ₓS₂ (where x is a real number between 0 to 1).

In this case, the binary compound, the ternary compound, or the quaternary compound may be present within particles at a uniform concentration, or present within the same particle in a state where concentration distributions are partially different. In some aspects, the compound may have a core/shell structure in which one quantum dot surrounds another quantum dot. The core/shell structure may have a concentration gradient in which the concentration of the elements present in the shell may gradually decrease toward the core.

In some embodiments, the quantum dots QD-C1, QD-C2, and QD-C3 may have a core-shell structure that includes a core including the above-described nanocrystal and a shell surrounding the core. The shell of the quantum dots QD-C1, QD-C2, and QD-C3 may serve as a protection layer for preventing the core from being chemically modified to maintain semiconductor properties and/or as a charging layer for imparting electrophoretic properties to the quantum dot. The shell may have a single layer or a multilayer. Examples of the shell of the quantum dots QD-C1, QD-C2, and QD-C3 may include an oxide of metal or non-metal, a semiconductor compound, a combination thereof, etc.

For example, the oxide of metal or non-metal may include: binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; or ternary compounds such as MgAl₂O₄, CoFe₂O₄, NiFe₂O₄, and CoMn₂O₄, but the inventive concept is not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the inventive concept is not limited thereto.

The quantum dots QD-C1, QD-C2, QD-C3 may have a full width of half maximum (FWHM) of an emission wavelength spectrum of about 45 nm or less, preferably about 40 nm or less, and more preferably about 30 nm or less, and when the FWHM falls within this range, color purity or color reproducibility may be improved. In some aspects, light emitted through the quantum dots QD-C1, QD-C2, and QD-C3 may be emitted in all directions, and thus an optical viewing angle may be improved.

In some aspects, shapes of the quantum dots QD-C1, QD-C2, and QD-C3 are shapes generally used in the art without particular limitation. However, more specifically, the shape of sphere, pyramid, multi-arm, or cubic nanoparticle, nanotube, nanowire, nanofiber, nanoplate particle, and the like, may be used.

By controlling the sizes of the quantum dots QD-C1, QD-C2, and QD-C3 or by controlling the element ratio in the quantum dot compound, the energy band gap of each quantum dot may be controlled, and thus light with various wavelength bands may be emitted in a quantum dot emission layer. Accordingly, by using such quantum dots (using quantum dots having different sizes or different element ratios in a quantum dot compound), a light-emitting element emitting light of various wavelengths may be achieved. Specifically, the sizes of the quantum dots QD-C1, QD-C2, and QD-C3 and the element ratio in the quantum dot compound may be controlled such that red, green, and/or blue light is emitted. In some aspects, the quantum dots QD-C1, QD-C2, and QD-C3 may be configured to emit white light by combining various colors of light.

The quantum dots QD-C1, QD-C2, and QD-C3 may control the color of emitted light depending on the particle size, and thus the quantum dots QD-C1, QD-C2, and QD-C3 may have various emission colors such as blue, red, and green. As the quantum dots QD-C1, QD-C2, and QD-C3 become smaller in particle size, the quantum dots may emit light of shorter wavelength regions. For example, in the quantum dots QD-C1, QD-C2, and QD-C3 having the same core, the particle size of the quantum dot which emits green light may be smaller than the particle size of the quantum dot which emits red light. In some aspects, in the quantum dots QD-C1, QD-C2, and QD-C3 having the same core, the particle size of the quantum dot which emits blue light may be smaller than the particle size of the quantum dot which emits green light. However, embodiments of the present disclosure are not limited thereto, and even in the quantum dots QD-C1, QD-C2, and QD-C3 having the same core, the particle size may be adjusted according to a shell forming material, a shell thickness, and the like.

When the quantum dots QD-C1, QD-C2, and QD-C3 have various emission colors such as blue, red, and green, materials for the cores of the quantum dots QD-C1, QD-C2, and QD-C3 having different emission colors may be different from each other.

In an embodiment, the first to third quantum dots QD-C1, QD-C2, and QD-C3 may have different diameters. For example, the first quantum dot QD-C1 used in the first light-emitting element ED-1, which emits light in a relatively short wavelength region, may have a relatively smaller average diameter than the second quantum dot QD-C2 in the second light-emitting element ED-2, and the third quantum dot QD-C3 in the third light-emitting element ED-3, which emit light in relatively long wavelength regions.

As used herein, the average diameter is an arithmetic mean value of particle diameters of a plurality of quantum dots. The particle diameter of the quantum dot particle may be an average value of the widths of the quantum dot particles on the cross-section thereof.

The relationship for the average diameter of the first to third quantum dots QD-C1, QD-C2, and QD-C3 is not limited to the above-described delimitation. That is, in FIG. 6, the first to third quantum dots QD-C1, QD-C2, and QD-C3 are illustrated to have sizes similar to each other, but, additional or alternative to the example illustrated, the first to third quantum dots QD-C1, QD-C2, and QD-C3 included in the light-emitting elements ED-1, ED-2, and ED-3 may have different sizes. In some aspects, two quantum dots selected from among the first to third quantum dots QD-C1, QD-C2, and QD-C3 may have average diameters similar to each other, but the other may have an average diameter different therefrom.

In the light-emitting elements ED-1, ED-2, and ED-3 according to an embodiment, the emission layers EML-B, EML-G, and EML-R may include a host and a dopant. In an embodiment, the emission layers EML-B, EML-G, and EML-R may include the quantum dots QD-C1, QD-C2, and QD-C3 as dopant materials. In some aspects, in an embodiment, the emission layers EML-B, EML-G, and EML-R may further include host materials. In the light-emitting elements ED-1, ED-2, and ED-3 according to an embodiment, the emission layers EML-B, EML-G, and EML-R may emit fluorescence. For example, the quantum dots QD-C1, QD-C2, and QD-C3 may be used as a fluorescent dopant material.

Although not illustrated, a ligand and the like may be bonded to each surface of the first to third quantum dots QD-C1, QD-C2, and QD-C3 for improving dispersion.

At least some of the first to third quantum dots QD-C1, QD-C2, and QD-C3 may include a fluoride ion bonded to the surface thereof. For example, the first to third quantum dots QD-C1, QD-C2, and QD-C3 may be provided in a state where a fluoride ion is bonded to respective surfaces of the first to third quantum dots QD-C1, QD-C2, and QD-C3. For example, each of the first to third quantum dots QD-C1, QD-C2, and QD-C3 may include a core and a shell covering the shell and include a fluoride ion bonded to the surface of shell. In some aspects, when each of the first to third quantum dots QD-C1, QD-C2, and QD-C3 further includes a ligand, the fluoride ion may also bind to the ligand. The fluoride ion bonded to the surface of the first to third quantum dots QD-C1, QD-C2, and QD-C3 may be derived from hydrofluoric acid that is used in a quantum dot preparing step to be described later.

In the display module DM illustrated in FIG. 5 and FIG. 6, the emission regions PXA-B, PXA-G, and PXA-R may have different areas from each other. In this case, the area may mean an area as viewed on the plane defined by the first direction DR1 and the second direction DR2.

The emission regions PXA-R, PXA-G, and PXA-B may have different areas according to colors of light emitted from the emission layers EML-B, EML-G, and EML-R in the light-emitting elements ED-1, ED-2, and ED-3. The blue emission region PXA-B of the first light-emitting element ED-1 emitting blue light may have the largest area, and the green emission region PXA-G of the second light-emitting element ED-2 emitting green light may have the smallest area. However, embodiments of the present disclosure are not limited thereto. The emission regions XA-R, PXA-G, and PXA-B may emit light with a different color other than red light, green light, and blue light. Alternatively, the emission regions PXA-R, PXA-G, and PXA-B may have the same area, or the emission regions PXA-R, PXA-G, and PXA-B may be provided at an area ratio differing from what is illustrated in FIG. 5.

The emission regions PXA-R, PXA-G, and PXA-B may be separated by the pixel-defining film PDL. The peripheral regions NPXA may be regions between the adjacent emission regions PXA-B, PXA-G, and PXA-R, and may correspond to the pixel-defining film PDL. In the present specification, the emission regions PXA-B, PXA-G, and PXA-R may respectively correspond to pixels.

In FIG. 6, the display element layer DP-EL may include a pixel-defining film PDL and first to third light-emitting elements ED-1, ED-2, ED-3. In the pixel-defining film PDL, a pixel opening OH may be defined.

The pixel-defining film PDL may separate the light-emitting elements ED-1, ED-2, and ED-3. The emission layers EML-B, EML-G, and EML-R in the light-emitting elements ED-1, ED-2, and ED-3 may be respectively disposed in openings OH defined in the pixel-defining films PDL and separated from each other. In an embodiment, the first emission layer EML-B of a first light-emitting element ED-1 may be disposed in a first opening OH1, the second emission layer EML-G of the second light-emitting element ED-2 may be disposed in a second opening OH2, and the third emission layer EML-R of the third light-emitting element ED-3 may be disposed in a third opening OH3.

The pixel-defining film PDL may be formed of a polymer resin. For example, the pixel-defining film PDL may be formed including a polyacrylate-based resin, or a polyimide-based resin. In some aspects, the pixel-defining film PDL may be formed further including an inorganic material in addition to a polymer resin. The pixel-defining film PDL may be formed including a light-absorbing material, or may be formed including a black pigment, or black dye. The pixel-defining film PDL formed including a black pigment or black dye may implement a black pixel-defining film. During the forming of the pixel-defining film PDL, carbon black and the like may be used as a black pigment or black dye, but embodiments of the present disclosure are not limited thereto.

In some aspects, the pixel-defining film PDL may be formed of an inorganic material. For example, the pixel-defining film PDL may be formed including silicon nitride (SiNₓ), silicon oxide (SiOₓ), silicon oxynitride (SiOₓN_{y}), silicon nitride-oxide (SiNₓO_{y}), and the like. The pixel-defining film PDL may define the emission regions PXA-R, PXA-G, and PXA-B. The emission regions PXA-B, PXA-G, and PXA-R and the peripheral region NPXA may be separated by the pixel-defining films PDL.

Each of the light-emitting elements ED-1, ED-2, and ED-3 may include a first electrode EL1, hole transport regions HTR-1, HTR-2, and HTR-3 disposed on the first electrode EL1, emission layers EML-B, EML-G, and EML-R disposed on the hole transport regions HTR-1, HTR-2, and HTR-3, and electron transport regions ETR-1, ETR-2, and ETR-3 disposed on the emission layers EML-B, EML-G, and EML-R, and a second electrode EL2 disposed on the electron transport regions ETR-1, ETR-2, and ETR-3.

The hole transport regions HTR-1, ETR-2, and HTR-3 and the electron transport regions ETR-1, ETR-2, and ETR-3 included in the respective light-emitting elements ED-1, ED-2, and ED-3 may be disposed in the openings OH1, OH2, and OH3 defined in the pixel-defining films PDL, and may be separated from each other.

For example, the first hole transport region HTR-1 and the first electron transport region ETR-1 included in the first light-emitting element ED-1 may be disposed adjacent to the first emission layer EML-B and may be patterned and disposed in the first opening OH1 in which the first emission layer EML-B is disposed. The second hole transport region HTR-2 and the second electron transport region ETR-2 included in the second light-emitting element ED-2 may be disposed adjacent to the second emission layer EML-G and may be patterned and disposed in the second opening OH2 in which the second emission layer EML-G is disposed. The third hole transport region HTR-3 and the third electron transport region ETR-3 included in the third light-emitting element ED-3 may be disposed adjacent to the third emission layer EML-R, and may be patterned and disposed in the third opening OH3 in which the third emission layer EML-R is disposed. However, embodiments of the present disclosure are not limited thereto, and the hole transport regions HTR-1, HTR-2, and HTR-3, and the electron transport regions ETR-1, ETR-2, and ETR-3 may each be provided as a common layer which is commonly disposed over the emission regions PXA-B, PXA-G, and PXA-R and the peripheral region NPXA.

In an embodiment, the hole transport regions HTR-1, HTR-2, and HTR-3, and the electron transport regions ETR-1, ETR-2, and ETR-3 may be respectively provided within the openings OH1, OH2, and OH3, defined in the pixel-defining films PDL, through a printing process.

Emission layers EML-B, EML-G, and EML-R may be disposed between the first electrode EL1 and the second electrode EL2. The light-emitting element ED according to an embodiment may include the quantum dots QD-C1, QD-C2, and QD-C3 in the emission layers EML-B, EML-G, and EML-R. In some aspects, the display module DM according to an embodiment includes first to third light-emitting elements ED-1, ED-2, and ED-3, which are distinguished from each other, and at least one among the first to third light-emitting elements ED-1, ED-2, and ED-3 may include quantum dots QD-C1, QD-C2, and QD-C3 in the emission layers EML-B, EML-G, and EML-R. For example, the emission layers EML-B, EML-G, and EML-R may respectively include a plurality of quantum dots QD-C1, QD-C2, and QD-C3. In an embodiment, the emission layers EML-B, EML-G, and EML-R may emit fluorescence. For example, the quantum dots QD-C1, QD-C2, and QD-C3 may be used as fluorescent dopant materials.

In an embodiment, the first light-emitting element ED-1 may include the first emission layer EML-B including the first quantum dot QD-C1, the second light-emitting element ED-2 may include the second emission layer EML-G including the second quantum dot QD-C2, and the third light-emitting element ED-3 may include the third emission layer EML-R including the third quantum dot QD-C3. In an embodiment, the first quantum dot QD-C1 may emit blue light, the second quantum dot QD-C2 may emit green light, and the third quantum dot QD-C3 may emit red light. However, embodiments of the present disclosure are not limited thereto, and the first to third light-emitting elements QD-C1, QD-C2, and QD-C3 may emit light in different wavelength regions other than blue, green, and red light.

The quantum dots QD-C1, QD-C2, and QD-C3 respectively included in the emission layers EML-B, EML-G, and EML-R may be stacked in association with forming a layer. FIG. 6 illustrates, as an example, that the quantum dots QD-C1, QD-C2, and QD-C3 having a cross-section in a circular shape are arranged to approximately form two layers, but embodiments of the present disclosure are not limited thereto. For example, the arrangement of the quantum dots QD-C1, QD-C2, and QD-C3 may vary in accordance with thicknesses of the emission layers EML-B, EML-G, and EML-R, shapes of the quantum dots QD-C1, QD-C2, and QD-C3 included in the emission layers EML-B, EML-G, and EML-R, an average diameter of the quantum dots QD-C1, QD-C2, and QD-C3, and the like. Specifically, in the emission layers EML-B, EML-G, and EML-R, the quantum dots QD-C1, QD-C2, and QD-C3 may be arranged such that the quantum dots QD-C1, QD-C2, and QD-C3 are adjacent to each other and form a single layer. In some examples, the quantum dots QD-C1, QD-C2, and QD-C3 may be arranged such that the quantum dots QD-C1, QD-C2, and QD-C3 form a plurality of layers such as two layers, three layers, or more. In some aspects, the emission layers EML-B, EML-G, and EML-R may further include light-emitting materials in addition to the quantum dots QD-C1, QD-C2, and QD-C3. In an embodiment, the emission layers EML-B, EML-G, and EML-R may further include fluorescent or phosphorescent dopant materials, or may further include a host material.

The quantum dots respectively constituting the first to third quantum dots QD-C1, QD-C2, and QD-C3 may include different materials. Alternatively, the first to third quantum dots QD-C1, QD-C2, and QD-C3 may be formed of the same quantum dot material, or two quantum dots selected from the first to third quantum dots QD-C1, QD-C2, and QD-C3 may be formed of the same material, and the other may be formed of a material therefrom.

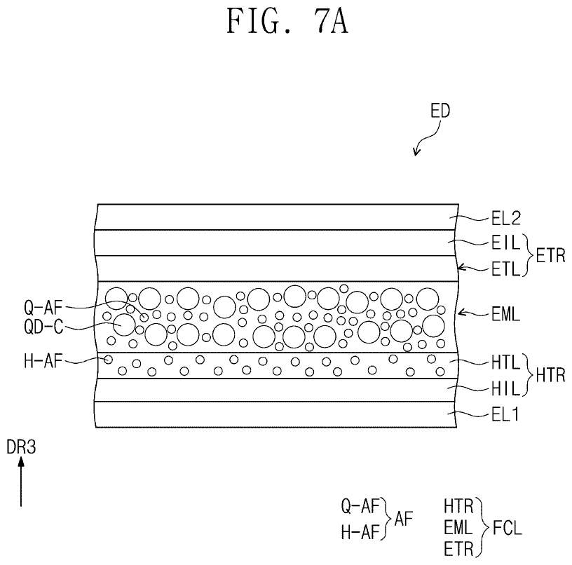

In the light-emitting elements ED-1, ED-2, and ED-3 according to an embodiment, the emission layers EML-B, EML-G, and EML-R, and the hole transport regions HTR-1, HTR-2, and HTR-3 each include a first fluoride source AF (see FIG. 7A).

At least one among the plurality of emission layers EML-B, EML-G, and EML-R included in the plurality of light-emitting elements ED-1, ED-2, and ED-3 according to an embodiment may include quantum dots QD-C1, QD-C2, or QD-C3, and the emission layers EML-B, EML-G, and EML-R including the quantum dots QD-C1, QD-C2, and QD-C3 and hole transport regions HTR-1, HTR-2, and HTR-3 adjacent thereto may each include the first fluoride source AF (see FIG. 7A).

In an embodiment, the first to third emission layers EML-B, EML-G, and EML-R included in the light-emitting elements ED-1, ED-2, and ED-3 may respectively include the quantum dots QD-C1, QD-C2, and QD-C3, and the first to third emission layers EML-B, EML-G, and EML-R, and hole transport regions HTR-1, HTR-2, and HTR-3 adjacent the first to third emission layers may each include the first fluoride source AF (see FIG. 7A).

The first fluoride source Q-AF (see FIG. 7A) included in the emission layers EML-B, EML-G, and EML-R may be spaced apart from the quantum dots QD-C1, QD-C2, and QD-C3 and present dispersed in the emission layers EML-B, EML-G, and EML-R. Alternatively, the first fluoride source Q-AF may be present bonded to a surface of each quantum dots QD-C1, QD-C2, and QD-C3. The first fluoride source Q-AF (see FIG. 7A) included in the emission layer EML may correspond to a fluoride source moved from the hole transport region to the emission layer during the forming of the emission layer in the method for manufacturing a light-emitting element to be described later.

The first fluoride source Q-AF (see FIG. 7A) included in the hole transport regions HTR-1, HTR-2, and HTR-3 may exist dispersed in the hole transport regions HTR-1, HTR-2, and HTR-3. In the hole transport regions HTR-1, HTR-2, and HTR-3, the first fluoride source H-AF (see FIG. 7A) may be present at a uniform concentration or non-uniform concentration. The details of the first fluoride sources Q-AF and H-AF (see FIG. 7A) included in the emission layers EML-B, EML-G, and EML-R, and the hole transport regions HTR-1, HTR-2, and HTR-3 will be described later with reference to FIG. 7A and FIG. 7B.

FIG. 6 illustrates that in the display module DM according to an embodiment, all emission layers EML-B, EML-G, and EML-R of the first to third light-emitting elements ED-1, ED-2, and ED-3 have the thicknesses similar to each other, but embodiments of the present disclosure are not limited thereto. For example, in an embodiment, the emission layers EML-B, EML-G, and EML-R of the first to third light-emitting elements ED-1, ED-2, and ED-3 may have different thicknesses.

The encapsulation layer TFE may cover the light-emitting elements ED-1, ED-2, and ED-3. The encapsulation layer TFE may seal the display element layer DP-EL. The encapsulation layer TFE may be a thin encapsulation layer. The encapsulation layer TFE may be a single layer, or a structure in which a plurality of layers is stacked. The encapsulation layer TFE may include at least one insulation layer. The encapsulation layer TFE according to an embodiment may include at least one inorganic layer (hereinafter, referred to as an encapsulation-inorganic layer). In some aspects, the encapsulation layer TFE according to an embodiment may include at least one organic layer (hereinafter, referred to as an encapsulation-organic layer).

The encapsulation-inorganic layer may protect the display element layer DP-EL from moisture/oxygen, and the encapsulation-organic layer may protect the display element layer DP-EL from foreign materials such as dust particles. The encapsulation-inorganic layer may include silicon nitride, silicon oxynitride, silicon oxide, titanium oxide, aluminum oxide, and the like, but is not particularly limited thereto. The encapsulation-organic layer may include an acrylate-based compound, an epoxy-based compound, and the like. The encapsulation-organic layer may include photopolymerizable organic materials but is not particularly limited thereto.

The encapsulation layer TFE may be disposed on the second electrode EL2, and may be disposed so as to fill in a portion of the openings OH1, OH2, and OH3.

In the display module DM illustrated in FIG. 5 according to an embodiment, all emission layers EML-B, EML-G, and EML-R of the first to third light-emitting elements ED-1, ED-2, and ED-3 are illustrated to have the thicknesses similar to each other, but embodiments of the present disclosure are not limited thereto. For example, in an embodiment, the emission layers EML-B, EML-G, and EML-R of the first to third light-emitting elements ED-1, ED-2, and ED-3 may have different thicknesses. In some aspects, each of the hole transport regions HTR-1, HTR-2, and HTR-3 and the electron transport regions ETR-1, ETR-2, and ETR-3 in the first to third light-emitting elements ED-1, ED-2, and ED-3 may have a different thickness.

Referring to FIG. 5, the blue emission regions PXA-B and the red emission regions PXA-R may be arranged in turns along the first direction DR1 and form a first group PXG1. The green emission regions PXA-G may be arranged along the first direction DR1 and form a second group PXG2. The first group PXG1 may be located to be spaced apart from the second group PXG2 in the second direction DR2. Each of the first group PXG1 and the second group PXG2 may be provided in a plurality of units. The first groups PXG1 and the second groups PXG2 may be arranged along the second direction DR2 in turns.

One red emission region PXA-R may be located to be spaced apart from one green emission region PXA-G in a fourth direction DR4. One blue emission region PXA-B may be located to be spaced apart from one green emission region PXA-G in a fifth direction DR5. The fourth direction DR4 may be a direction between the first direction DR1 and the second direction DR2. The fifth direction DR5 may be a direction that crosses the fourth direction DR4 and is inclined with respect to the second direction DR2.

An arrangement structure of the emission regions PXA-B, PXA-G, and PXA-R illustrated in FIG. 5 may be referred to as a pentile-structure. The arrangement structure of the emission regions PXA-R, PXA-G, and PXA-B is not limited to the arrangement structure illustrated in FIG. 5. For example, the emission regions PXA-R, PXA-G, and PXA-B may have a stripe structure in which the red emission region PXA-R, the green emission region PXA-G, and the blue emission region PXA-B are sequentially arranged in turns along the first direction DR1. In some aspects, on the plane, shapes of the emission layers PXA-B, PXA-G, and PXA-R are not limited to what is illustrated and may be defined in a different shape from what is illustrated.

Referring to FIG. 6, the display module DM according to an embodiment may further include an optical member PP. The optical member PP may block external light provided on the display panel DP from outside the display module DM. The optical member PP may block a portion of external light. The optical member PP may serve an anti-reflection function that minimizes reflection caused by external light.

In an embodiment as illustrated in FIG. 6, the optical member PP may include a base layer BL and a color filter layer CFL. The display module DM according to an embodiment may further include the color filter layer CFL disposed on the light-emitting elements ED-1, ED-2, and ED-3 of the display panel DP.

The base layer BL may be a member providing a base surface in which the color filter layer CLF is disposed. The base layer BL may be a glass substrate, a metal substrate, a plastic substrate, and the like. However, embodiments of the present disclosure are not limited thereto, and the base layer BL may be an inorganic layer, an organic layer, or a composite material layer.

The color filter layer CFL may include first to third filters CF-B, CF-G, and CF-R. The first to third filters CF-B, CF-G, and CF-R may be disposed so as to correspond respectively to the first to third light-emitting elements ED-1, ED-2, and ED-3. For example, the first filter CF-B may be a blue filter, the second filter CF-G may be a green filter, and the third filter CF-R may be a red filter. The first to third filters CF-B, CF-G, and CF-R may be disposed corresponding to the first to third emission regions PXA-B, PXA-G, and PXA-R, respectively.

The first to third filters CF-B, CF-G, and CF-R may each include a polymer photosensitive resin and a pigment or dye. The first filter CF-B may include a blue pigment or blue dye, the second filter CF-G may include a green pigment or green dye, and the third filter CF-R may include a red pigment or red dye. However, embodiments of the present disclosure are not limited thereto, and the first filter CF-B may include no pigment or no dye. The first filter CF-B may include a polymer photosensitive resin and include no pigment or no dye. The third filter CF-B may be transparent. The third filter CF-B may be formed of a transparent photosensitive resin.

The color filter layer CFL may further include a buffer layer BFL. For example, the buffer layer BFL may be a protection layer that protects the first to third filters CF-B, CF-G, and CF-R. The buffer layer BFL may be an inorganic layer including at least one inorganic material of silicon nitride, silicon oxide, or silicon oxynitride. The buffer BFL may include a single layer or a plurality of layers.

In some aspects, the second filter CF-G and the third filter CF-R may each be a yellow filter. The second filter CF-G and the third filter CF-R may be provided as an integrated unit without being distinguished from each other.

In an embodiment, as illustrated in FIG. 6, the first filter CF-B of the color filter layer CFL overlaps the second filter CF-G and the third filter CF-R, but embodiments of the present disclosure are not limited thereto. For example, the first to third filters CF-B, CF-G, and CF-R may be separated by a light-blocking part (not illustrated) and may not overlap each other. In an embodiment, the first to third filters CF-B, CF-G, and CF-R may be respectively disposed corresponding to the blue emission region PXA-B, the green emission region PXA-G, and the red emission region PXA-R. In the display module DM according to an embodiment, the color filter layer CFL may be omitted.

Although not illustrated, the color filter layer CFL may further include a light-blocking part (not illustrated). The light-blocking part may be a black matrix. The light-blocking part may be formed of organic light-blocking materials or inorganic light-blocking materials, containing a black pigment or black dye. The light-blocking part may prevent a light leakage phenomenon and separate boundaries between the adjacent filters CF-B, CF-G, and CF-R.

Additional or alternative to the example illustrated in FIG. 6, the display module DM according to an embodiment may include a polarization layer (not illustrated) instead of the color filter layer CFL. The polarization layer (not illustrated) may block external light provided on the display panel DP from the outside. The polarization layer (not illustrated) may block a portion of external light.

In some aspects, the polarization layer (not illustrated) may reduce reflected light of the external light at the display panel DP. For example, the polarization layer (not illustrated) may serve to block reflected light when light provided from the outside is incident on the display panel DP and then re-emitted. The polarization layer (not illustrated) may be a circular polarizer having an anti-reflection function, or the polarization layer (not illustrated) may include a linear polarizer and λ/4 phase retarder. The polarization layer (not illustrated) may be disposed on the base layer BL to be exposed, or the polarization layer (not illustrated) may be disposed below the base layer BL.

FIG. 7A is a cross-sectional view illustrating a light-emitting element according to an embodiment of the inventive concept. FIG. 7B is a cross-sectional view illustrating some components of a light-emitting element according to an embodiment of the inventive concept. The details for the light-emitting element ED described in FIG. 7A may be similarly applied to at least one among the first to third light-emitting elements ED-1, ED-2, or ED-3.

Referring to FIG. 7A, the light-emitting element ED includes a first electrode EL1, a functional layer FCL, and a second electrode EL2, which are sequentially stacked. The functional layer FCL may include a hole transport region HTR, an emission layer EML, and an electron transport region ETR.

In the light-emitting element ED according to an embodiment, the first electrode EL1 has conductivity. The first electrode EL1 may be formed of a metal alloy or a conductive compound. The first electrode EL1 may be an anode. The first electrode EL1 may be a pixel electrode.

In the light-emitting element ED according to an embodiment, the first electrode EL1 may be a reflective electrode. However, embodiments of the present disclosure are not limited thereto. For example, the first electrode EL1 may be a transmissive electrode or a transflective electrode. In an example in which the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg). Alternatively, the first electrode EL1 may have a multi-layered structure including a reflective or transflective layer formed of the example material, or a transparent conductive layer formed of indium tin oxide (ITO), indium zinc oxide (IZO), zinc oxide (ZnO), indium tin zinc oxide (ITZO), and the like. For example, the first electrode EL1 may be a multi-layered metal layer and a stacked structure of metal layers of ITO/Ag/ITO.

In the light-emitting element ED according to an embodiment, an emission layer EML and a hole transport region HTR may each include a first fluoride source AF. As used herein, in the light-emitting element ED according to an embodiment, the first fluoride source AF included in the hole transport region HTR may be referred to as a first sub fluoride source H-AF, and the fluoride source included in the emission layer EML may be referred to as a second sub fluoride source Q-AF. The first sub fluoride source H-AF included in the hole transport region HTR may be the same as the second sub fluoride source Q-AF included in the emission layer EML. The second sub fluoride source Q-AF included in the emission layer EML corresponds to a fluoride source which moves from the hole transport region to the emission layer during the forming of the emission layer in the method for manufacturing a light-emitting element to be described later. The fluoride source included in the hole transport region HTR and the fluoride source included in the emission layer EML correspond to the same fluoride source.

Referring to FIG. 7A, the hole transport region HTR is provided on the first electrode EL1. The hole transport region HTR may include a hole injection layer HIL, a hole transport layer HTL, and the like. In some aspects, the hole transport region HTR may further include at least one of a hole buffer layer (not illustrated), or an electron blocking layer (not illustrated), in addition to the hole injection layer HIL and the hole transport layer HTL. The hole buffer layer (not illustrated) may compensate a resonance distance depending on a wavelength of light emitted in the emission layer EML, and thus light-emitting efficiency may be improved. As materials included in the hole buffer layer (not illustrated), materials that may be included in the hole transport region HTR may be used. The electron blocking layer (not illustrated) is a layer which serves to prevent electrons from being injected from the electron transport region ETR to the hole transport region HTR.

Referring to FIG. 7A again, the hole transport regions HTR may each have a single layer formed using a single material, a single layer formed using a plurality of different materials, or a multi-layered structure having a plurality of layers formed of a plurality of different materials. For example, the hole transport region HTR may have a structure of a single layer formed of a plurality of different materials, or may have a structure of hole injection layer HIL/hole transport layer HTL, hole injection layer HIL/hole transport layer HTL/hole buffer layer (not illustrated), hole injection layer HIL/hole buffer layer (not illustrated), hole transport layer HTL/hole buffer layer (not illustrated), or hole injection layer HIL/hole transport layer HTL/electron blocking layer (not illustrated), sequentially stacked from the first electrode EL1, but embodiments of the present disclosure are not limited thereto.

The hole transport region HTR may include a hole transport material and a first sub fluoride source H-AF. The first sub fluoride source H-AF may refer to a fluorine compound that contains fluorine. The first sub fluoride source H-AF may refer to a low-molecular-weight fluorine compound that contains fluorine. The first sub fluoride source H-AF may include at least one among low-molecular-weight fluorine compounds including at least one functional group of —CF₃, —CF₂—, —CF₂CF₂—, —CF₂CH₂—, —OCF=CF₂, or —OCF₂—, substituted or unsubstituted fluorinated aromatic compounds, and fluorinated azide compounds.

As used herein, the “fluorinated aromatic compound” refers to a compound having an aromatic moiety and containing an aryl carbon-fluorine bond. That is, the fluorinated aromatic compound may mean a compound having a form in which at least one hydrogen atom bonded to an aryl carbon that constitutes the aromatic moiety is substituted with a fluorine atom. In an example in which the fluorinated aromatic compound is substituted, at least one among the substituents may include a carbon-fluorine bond but is not limited thereto.

As used herein, a “fluorinated azide compound” refers to a compound having an azide (—N—N≡N, or N₃) moiety and containing a carbon-fluorine bond. The carbon-fluorine bond may include —CF₃, —CF₂—, —CF₂CF₂—, —CF₂H, —CH₂CF₃, —CH₂CF₃CF₂H, —CH₂CF₂H, —OCF=CF₂, —OCF₂—, —CF₂C═OCOR, —CF₂C═OCNH₂, and the like. Herein, R is a substituted or unsubstituted C_{1 to 20} alkyl group. The “fluorinated azide compound” may include one or more azide moieties.

In an embodiment, the first sub fluoride source H-AF may further include a first functional group. The first functional group may mean a cross-linkable functional group. Alternatively, the first functional group may be a functional group that is capable of forming a chemical bond with a ligand. In an embodiment, the first functional group may include a nucleophilic functional group, or an electrophilic functional group. For example, the first functional group may include at least one of a thiol group, an amine group, a hydroxy group, an azide group, a (meth)acrylate group, an epoxy group, a glycidyl group, an oxetanyl group, an alkenyl group, an alkynyl group, a carboxyl group, of an acyl halide group.

When the hole transport region HTR is a multi-layered structure having a plurality of layers, any one layer among the plurality of layers may include the first sub fluoride source H-AF. For example, as illustrated in FIG. 7A, the hole transport region HTR may include a hole injection layer HIL disposed on the first electrode EL1, and a hole transport layer HTL disposed on the hole injection layer HIL, and the hole transport layer HTL may include the first sub fluoride source H-AF. Additional or alternative to the example illustrated in FIG. 7A, each of the hole transport layer HTL and the hole injection layer HIL may include the first sub fluoride source H-AF according to an embodiment.

In an embodiment, a layer adjacent to the emission layer EML, among the plurality of layers included in the hole transport region HTR, may include the first sub fluoride source H-AF. For example, the hole transport region HTR may include a hole injection layer HIL disposed on the first electrode EL1, and a hole transport layer HTL that is disposed on the hole injection layer HIL and is in contact with the emission layer EML, and the hole transport layer HTL may include the first sub fluoride source H-AF. Since the layer adjacent to at least the emission layer EML, among the plurality of layers included in the hole transport region HTR, includes the first sub fluoride source H-AF, the first sub fluoride source H-AF may easily move from the hole transport region HTR to the emission layer EML during the manufacturing or driving of the light-emitting element, and thus a passivation effect on the quantum dot QD-C, of the first fluoride source H-AF may be improved.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method. In an embodiment, the hole transport region HTR may be formed provided by the inkjet printing method.

The hole transport material included in the hole transport region HTR may be a known inorganic material or a known organic material. For example, the hole transport material included in the hole transport region HTR may be an organic material.

The hole transport region HTR may include a compound represented by Formula H-1 below as a hole transport material.

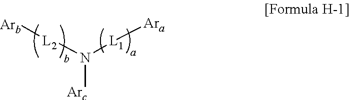

In Formula H-1 above, L₁ and L₂ may be each independently a direct linkage, a substituted or unsubstituted arylene group having 6 to 30 ring-forming carbon atoms, or a substituted or unsubstituted heteroarylene group having 2 to 30 ring-forming carbon atoms. a and b may be each independently an integer of 0 to 10.

If a or b is an integer of 2 or greater, a plurality of L₁ and L₂ may be each independently a substituted or unsubstituted arylene group having 6 to 30 ring-forming carbon atoms, or a substituted or unsubstituted heteroarylene group having 2 to 30 ring-forming carbon atoms.

In Formula H-1, Arₐ and Ar_{b} may be each independently a direct linkage, a substituted or unsubstituted aryl group having 6 to 30 ring-forming carbon atoms, or a substituted or unsubstituted heteroaryl group having 2 to 30 ring-forming carbon atoms. In some aspects, in Formula H-1, Ar_{c} may be a substituted or unsubstituted aryl group having 6 to 30 ring-forming carbon atoms.

A compound represented by Formula H-1 above may be a monoamine compound. Alternatively, the compound represented by Formula H-1 above may be a diamine compound in which at least one among Arₐ to Ar_{c} includes an amine group as a substituent. In some aspects, the compound represented by Formula H-1 above may be a carbazole-based compound in which a substituted or unsubstituted carbazolyl group is included in at least one among Arₐ and Ar_{b}, or a fluorene-based compound in which a substituted or unsubstituted fluorene group is included in at least one among Arₐ and Ar_{b}.

The compound represented by Formula H-1 may be represented by any one among compounds in Compound Group H below. However, the compounds present in Compound Group H below are suggested as examples, and the compound represented by Formula H-1 is not limited to the compounds present in Compound Group H below.

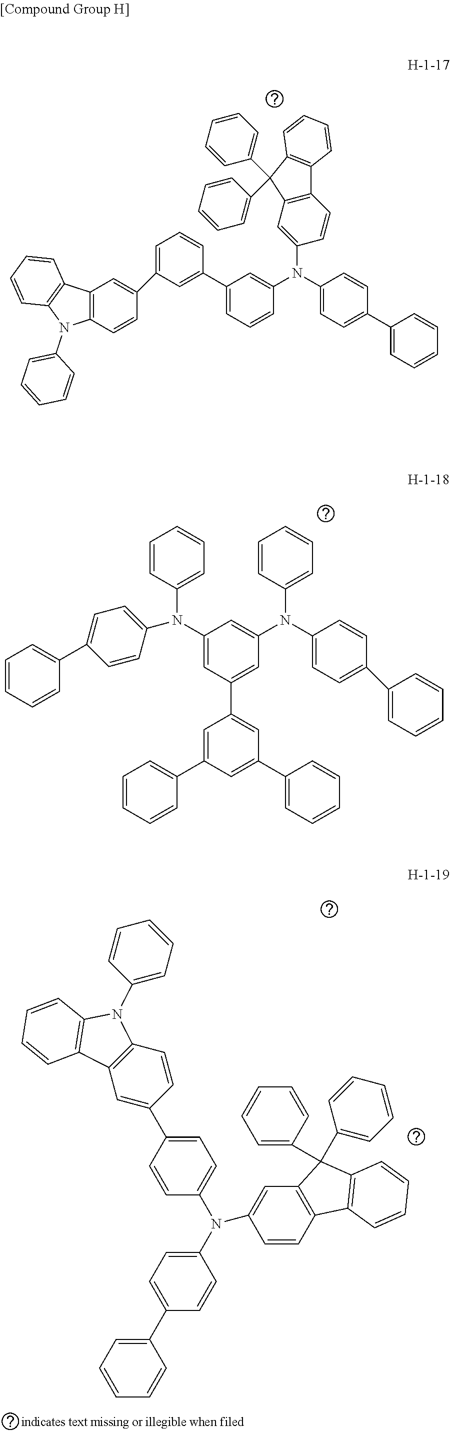 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include, as a hole transport material, a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPD), polyether ketone containing triphenylamine (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), etc.

The hole transport region HTR may include a general material known to the related technical field as a hole transport material. For example, the hole transport region HTR may include carbazole-based derivatives such as N-phenyl carbazole and polyvinyl carbazole, fluorine-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), N,N′-di(naphthalene-1-yl)-N,N′-diphenyl-benzidine (NPD), 4,4′-cyclohexylidene bis[N,N-bis(4-methylphenyl)benzenamine]) ((TAPC), 4,4′-bis[N,N′-(3-tolyl)amino]-3,3′-dimethylbiphenyl (HMTPD), 1,3-bis(N-carbazolyl)benzene (mCP), etc.

In some aspects, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described hole transport materials in at least one among the hole injection layer HIL, the hole transport layer HTL, and the electron blocking layer EBL.

The hole transport region HTR may have a thickness of about 5 nm to about 1500 nm, for example, about 10 nm to about 500 nm. The hole injection layer HIL may have a thickness of, for example about 3 nm to about 200 nm, and the hole transport layer HTL may have a thickness of about 3 nm to about 100 nm. For example, the electron blocking layer (not illustrated) may have a thickness of about 1 nm to about 100 nm. In an example in which each of the hole transport region HTR, hole injection layer HIL, hole transport layer HTL, and electron blocking layer (not illustrated) have a thickness falling within the above-described ranges, hole transport properties in a satisfactory degree may be obtained without an increase in driving voltage.

The emission layer EML may be provided on the hole transport region HTR. The emission layer EML may be provided on the hole transport region HTR. The emission layer EML may have a thickness of, for example, about 10 nm to about 100 nm, or about 10 nm to about 30 nm. The emission layer EML may have a single layer formed using a single material, a single layer formed using a plurality of different materials, or a multi-layered structure having a plurality of layers formed using a plurality of different materials.

In the light-emitting element ED according to an embodiment, the emission layer EML may include a quantum dot QD-C. Hereinafter, the details for the first to third quantum dots QD-C1, QD-C2, and QD-C3 in FIG. 6 may be similarly applied to the quantum dot QD-C.

Referring to FIGS. 7A and 7B together, the quantum dot QD-C may include a core CO and a shell SH covering the core CO. The shell SH may cover the core CO. The shell SH may entirely cover the core CO. Therefore, a surface of the quantum dot QD-C may be defined by an exterior of the shell SH. The core CO may be unexposed in the quantum dot QD-C since being covered by the shell SH.

The quantum dot QD-C may further include a ligand LD bonded to the surface of the quantum dot QD-C. The quantum dot QD-C may be manufactured by a chemical wet method to include a ligand LD which is coordinated to the surface. As the ligand LD, most of known ligand compounds may be used without particular limitation. For example, the ligand LD may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH, or a combination thereof. Herein, R, and R′ may be each independently a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, or a substituted or unsubstituted aryl group having 6 to 30 ring-forming carbon atoms.

The ligand LD coordinates to the surface of the prepared quantum dot QD-C, may support effective dispersal of the quantum dot QD-C in a solution, and may influence on luminous and electrical characteristics. Examples of the ligand LD may include methanethiol, ethanethiol, propanethiol, butanethiol, pentanethiol, hexanethiol, octanethiol, dodecanethiol, hexadecanethiol, octadecanethiol, benzylthiol; methanamine, ethanamine, propanamine, butylamine, pentylamine, hexylamine, octylamine, dodecylamine, hexadecylamine, octadecylamine, dimethylamine, diethylamine, dipropylamine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, substituted or unsubstituted methylphosphines such as trimethylphosphine, and methyldiphenylphosphine, substituted or unsubstituted ethylphosphines such as triethylphosphine, and ethyldiphenylphosphine, substituted or unsubstituted propylphosphines, substituted or unsubstituted butylphosphines, substituted or unsubstituted pentylphosphines, substituted or unsubstituted octylphosphines such as trioctylphosphine, substituted or unsubstituted methylphosphine oxides such as trimethylphosphine oxide, and methyldiphenylphosphine oxide, substituted or unsubstituted ethylphosphine oxides such as triethylphosphine oxide, and ethyldiphenylphosphine oxide, substituted or unsubstituted propylphosphine oxides, substituted or unsubstituted butylphosphine oxides, octylphosphine oxides such as trioctylphosphine oxide (TOPO), diphenylphosphine, triphenylphosphine compounds or oxide compounds thereof, phosphonic acid, and the like, but are not limited thereto. The above-described material may be used alone, or a mixture of two or more thereof may be used as the ligand LD.

The quantum dot QD-C may further include a fluoride ion (FI). The fluoride ion (FI) may exist bonded to the quantum dot QD-C. The fluoride ion (FI) may be bonded to at least one of the surface of the core CO or the surface of the shell SH, which are included in the quantum dot QD-C. For example, as described in FIG. 7B, the fluoride ion (FI) may exist bonded to each surface of the core CO and the shell SH. In some aspects, the fluoride ion (FI) may exist bonded to the ligand LD. The fluoride ion (FI) included in the emission layer EML may be formed through treating fluorine during manufacturing a quantum dot in the method for manufacturing a light-emitting element to be described later.

The emission layer EML includes a second sub fluoride source Q-AF. The second sub fluoride source Q-AF may refer to a fluorine compound that contains fluorine. The second sub fluoride source Q-AF may be a low-molecular-weight fluorine compound that contains fluorine. The second sub fluoride source Q-AF may include at least one of a low-molecular-weight compound, which includes at least one functional group of —CF₃, —CF₂—, —CF₂CF₂—, —CF₂CH₂—, —OCF═CF₂, or —OCF₂—, or a substituted or unsubstituted fluorinated aromatic compound.

In an embodiment, the second sub fluoride source Q-AF may further include a second functional group. The second functional group may mean a cross-linkable functional group. Alternatively, the second functional group may be a functional group that is capable of forming a chemical bond with a ligand. In an embodiment, the second functional group may include a nucleophilic functional group, or an electrophilic functional group. For example, the second functional group may include at least one of a thiol group, an amine group, a hydroxy group, an azide group, a (meth)acrylate group, an epoxy group, a glycidyl group, an oxetanyl group, an alkenyl group, an alkynyl group, a carboxyl group, or an acyl halide group.

In an embodiment, the second sub fluoride source Q-AF included in the emission layer EML may be the same as the first sub fluoride source H-AF included in the hole transport region HTR. The second sub fluoride source Q-AF included in the emission layer EML may move from the hole transport region HTR to the emission layer EML during the forming of the emission layer in the method for manufacturing a light-emitting element according to an embodiment to be described later. Therefore, the fluoride source included in the hole transport region HTR may be the same as the fluoride source included in the emission layer EML. This will be described later.

The second sub fluoride source Q-AF included in the emission layer EML may be dispersed in the emission layer EML and exist to be spaced apart from the quantum dot QD-C. The second sub fluoride source Q-AF may be present in the emission layer EML at a uniform concentration or at a non-uniform concentration. Although not illustrated, the second sub fluoride source Q-AF may be present to be bonded to the surface of the quantum dot QD-C. Since the second sub fluoride source Q-AF is bonded to the surface of the quantum dot QD-C, the number of surface trap states caused by dangling bond, and the like may be reduced. The second sub fluoride source Q-AF may be bonded to a surface defect of the quantum dot QD-C, which may occur during synthesis of quantum dot, manufacture of a light-emitting element, or driving a light-emitting element, and thus decreases in emission characteristics may be minimized by suppressing formation of the defects in the quantum dot QD-C.

The concentration of fluorine in the emission layer EML measured before applying a voltage to the light-emitting element ED may be different from the concentration of fluorine in the emission layer EML measured after applying the voltage to the light-emitting element ED for a predetermined time. That is, depending on driving time of the light-emitting element ED, the concentration of fluorine in the emission layer EML may vary. In an example in which the voltage is applied to the light-emitting element ED, the concentration of fluorine in the emission layer EML may gradually increase over time. In an example in which the concentration of fluorine in the emission layer EML measured before applying the voltage to the light-emitting element ED is set as a reference concentration, the concentration of fluorine in the emission layer EML measured after applying the voltage to the light-emitting element ED may gradually increase from the reference concentration. During driving the light-emitting element ED, a portion of the first sub fluoride source H-AF included in the hole transport region HTR may move to the emission layer EML. Therefore, the concentration of fluorine in the emission layer EML may gradually increase.

A change in concentration of fluorine in the emission layer EML over time, before and after driving, may be identified using secondary ion mass spectrometry (SIMS), but is not limited thereto. For example, the reference concentration of fluorine in the emission layer EML is measured using the secondary ion mass spectrometry before the driving, a change in the concentration of fluorine in the emission layer EML is measured after driving for a predetermined time, and then the reference concentration is compared with the concentration of fluorine in the emission layer EML after driving, thereby capable of measuring the change in fluorine concentration.

The emission layer EML may be formed using various methods such as a vacuum deposition method, a spin coating method, a cast method, a Langmuir-Blodgett (LB) method, an inkjet printing method, a laser printing method, and a laser induced thermal imaging (LITI) method. In an embodiment, the emission layer EML may be formed by providing a quantum dot composition including the quantum dot QD-C using an inkjet printing method.

In the light-emitting element according to an embodiment of the inventive concept, since each of the emission layer EML and the hole transport region HTR includes the first fluoride source Q-AF, and H-AF, passivation effects on the quantum dot QD-C may be increased. The first fluoride source Q-AF and H-AF may be provided so as to be bonded to a defect part present in the surface of the quantum dot QD-C, and thus electrical characteristics of the quantum dot QD-C may be improved through defect passivation effect. During the driving of the light-emitting element, the fluoride ion (FI) bonded to the quantum dot QD-C may be detached, and thus defects in the quantum dot QD-C may increase. Accordingly, depending on the driving time, limitations such as changes in luminous characteristics and deterioration of element lifespan characteristics may be caused. However, according to the inventive concept, since each of the emission layer EML and the hole transport region HTR includes the first fluoride sources Q-AF and H-AF, lost fluoride ion from the quantum dot QD-C during the driving may be replenished. That is, the first fluoride sources Q-AF and H-AF recombine the defect site formed by detachment of the fluoride ion (FI) from the quantum dot QD-C during driving, and thus defect formation in the quantum dot QD-C may be suppressed, thereby capable of minimizing deterioration in light-emitting characteristics. Accordingly, even during the long time of driving, changes in light-emitting characteristics of the quantum dot QD-C are not significant, and thus element stability according to the driving time may be improved.

Referring to FIG. 7A again, in the light-emitting element ED according to an embodiment, an electron transport region ETR is provided on the emission layer EML. The electron transport region ETR may include at least one of a hole blocking layer (not illustrated), an electron transport layer ETL, or an electron injection layer EIL, but embodiments of the present disclosure are not limited thereto.

The electron transport region ETR may have a single layer formed of a single material, a single layer formed of a plurality of different materials, or a multi-layered structure having a plurality of layers formed of a plurality of different materials.

For example, the electron transport region ETR may have a structure of an electron injection layer EIL or electron transport layer ETL, and may also have a single-layered structure formed using an electron injection material and an electron transport material. In some aspects, the electron transport region ETR may have a single-layered structure formed using a plurality of different materials, or may have a structure of electron transport layer ETL/electron injection layer EIL, hole blocking layer HBL/electron transport layer ETL/electron injection layer EIL, which are stacked from the emission layer EML in turns, but is not limited thereto. The electron transport region ETR may have a thickness of, for example, about 20 nm to about 150 nm.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method. In an embodiment, the electron transport region ETR may be formed using a vacuum deposition method, or an inkjet printing method.

In an embodiment, the electron transport region ETR may include a known inorganic material or a known organic material.

When the electron transport region ETR includes the electron transport layer ETL, the electron transport region ETR may include an anthracene-based compound. However, embodiments of the present disclosure are not limited thereto, and the electron transport region may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi), 2,9-Dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), or a mixture thereof. The electron transport layer ETL may have a thickness of about 10 nm to about 100 nm, for example, about 15 nm to about 50 nm. In an example in which each thickness of the electron transport layers ETL falls within the above-described range, electron transport characteristics to a satisfactory degree may be obtained without a substantial increase in driving voltage.

When the electron transport region ETR includes the electron injection layer EIL, the electron transport region ETR may include metal halides such as LiF, NaCl, CsF, RbCl, and RbI, lanthanide metals such as Yb, metal oxides such as Li₂O, and BaO, lithium quinolate (LiQ), and the like, but is not limited thereto. The electron injection layer EIL may also be formed using mixed materials of an electron transport material and an organo metal salt having insulating properties. For example, the organo metal salt may include metal acetates, metal benzoates, metal acetoacetates, metal acetylacetonates, or metal stearates. The electron injection layers EIL may have a thickness of about 0.1 nm to about 10 nm, for example, about 0.3 nm to about 9 nm. In an example in which each thickness of the electron injection layers EIL falls within the above-described range, electron injection characteristics to a satisfactory degree may be obtained without a substantial increase in driving voltage.

The electron transport region ETR may include a hole blocking layer HBL, as described previously. The hole blocking layer HBL may include, for example, at least one of 2,9-dimethyl-4,7-diphenyl-1,10-phenanthroline (BCP), or 4,7-diphenyl-1,10-phenanthroline (Bphen), but is not limited thereto.

The second electrode EL2 is provided on the electron transport region ETR. The second electrode EL2 may be a common electrode or a negative electrode. The second electrode EL2 may be a transmissive electrode, a transflective electrode, or a reflective electrode. In an example in which the second electrode EL2 is a transmissive electrode, the second electrode EL2 may be formed using transparent metal oxides such as indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, or a compound or mixture including the same (e.g., a mixture of Ag and Mg). Alternatively, the second electrode EL2 may have a multi-layered structure including a reflective or transflective layer formed of the above-described material, or a transparent conductive layer formed of indium tin oxide (ITO), indium zinc oxide (IZO), zinc oxide (ZnO), indium tin zinc oxide (ITZO), etc.

Although not illustrated, the second electrode EL2 may be connected to an auxiliary electrode. If the second electrode EL2 is connected to the auxiliary electrode, resistance of the second electrode EL2 may decrease.

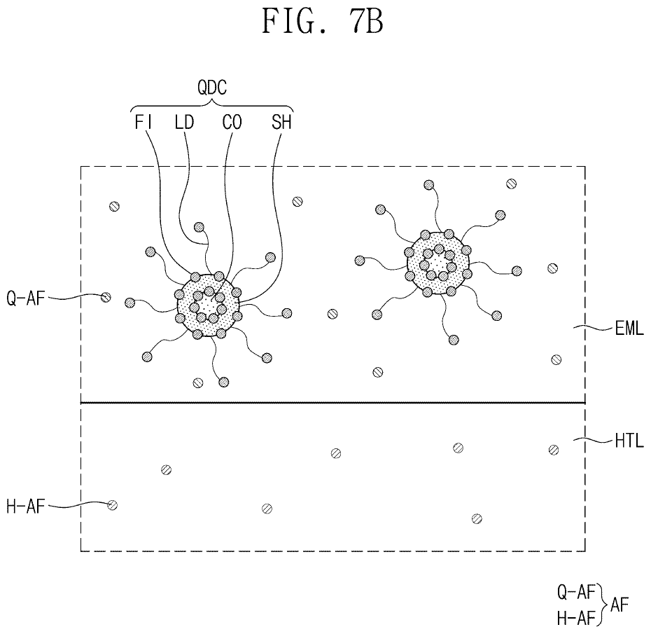

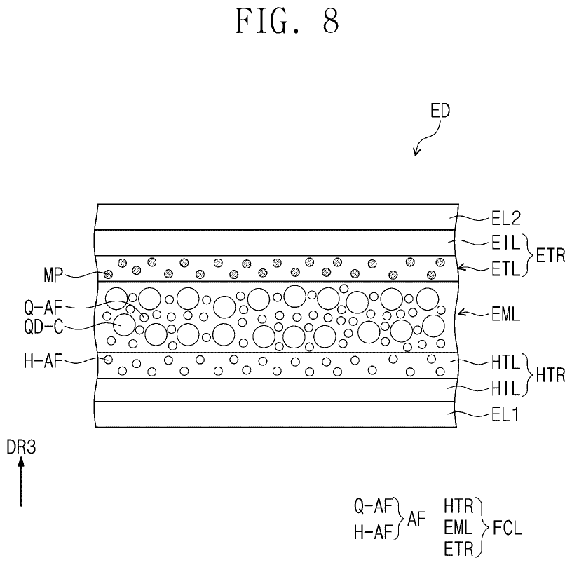

FIG. 8 is a cross-sectional view illustrating a light-emitting element according to an embodiment of the inventive concept. FIG. 8 illustrates a light-emitting element ED-a according to another embodiment, which is different from the light-emitting element according to an embodiment illustrated in FIG. 8. The details for the light-emitting element ED in FIG. 8 may be similarly applied to at least one among the first to third light-emitting elements ED-1, ED-2, and ED-3, illustrated in FIG. 6. In descriptions for FIG. 8, the duplicated content as the details in FIG. 3 to FIG. 7B, and the like will not be explained again, and differences will be mainly described.

Compared to the light-emitting element ED illustrated in FIG. 7A and FIG. 7B, a light-emitting element ED-a illustrated in FIG. 8 differs where the electron transport region ETR includes an inorganic particle MP.

In an embodiment, the inorganic particle MP may include metal oxides including at least one of silicon, aluminum, zinc, indium, gallium, yttrium, germanium, scandium, titanium, tantalum, hafnium, zirconium, cerium, molybdenum, nickel, chromium, iron, niobium, tungsten, tin, or copper, or mixtures thereof, but is not limited thereto.

In an embodiment, the inorganic particle MP may include at least one of zinc oxide or tin oxide. Types of zinc oxides are not particularly limited, but ZnO may be used, or Sn, Mg, Ca, or the like may be doped. The zinc oxides may be SnO, SnO₂, or a combination thereof.

In an embodiment, the inorganic particle MP may include at least one of ZnO, ZnSnO, ZnMgO, SnO₂, or ZnGaO.

The electron transport region ETR may be formed using an electron transport composition including an inorganic particle MP. For example, the electron transport region ETR may be formed using an electron transport composition including an inorganic particle MP and a solvent. For the solvent, descriptions for a solvent of an ink composition ICP to be described later will be similarly applied.

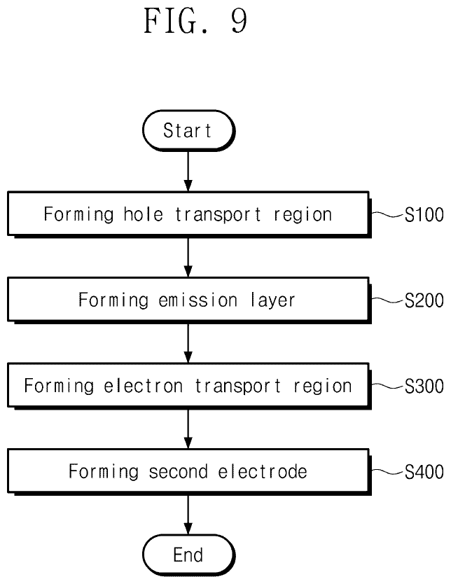

FIG. 9 is a flow chart illustrating a method for manufacturing a light-emitting element according to an embodiment.

Referring to FIG. 9, the method for manufacturing a light-emitting element according to an embodiment includes forming a hole transport region on a first electrode (S100), forming an emission layer on the hole transport region (S200), forming an electron transport region on the emission layer (S300), and forming a second electrode on the electron transport region (S400).

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added.

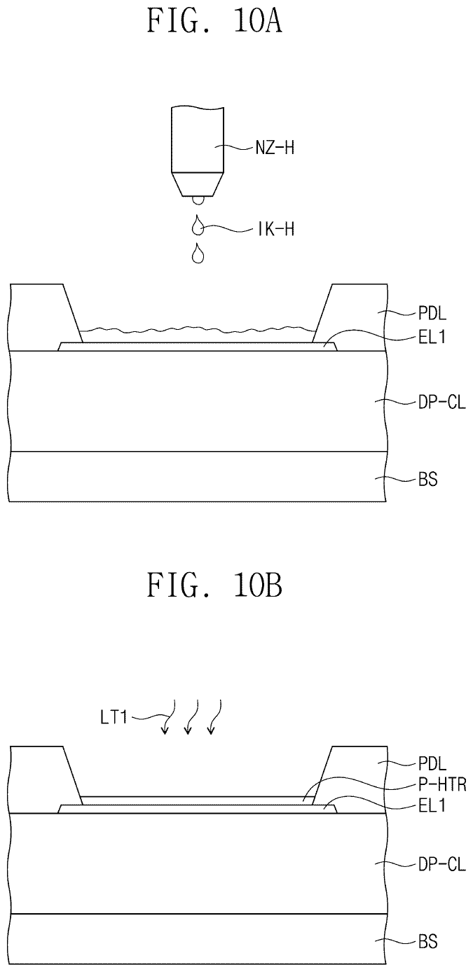

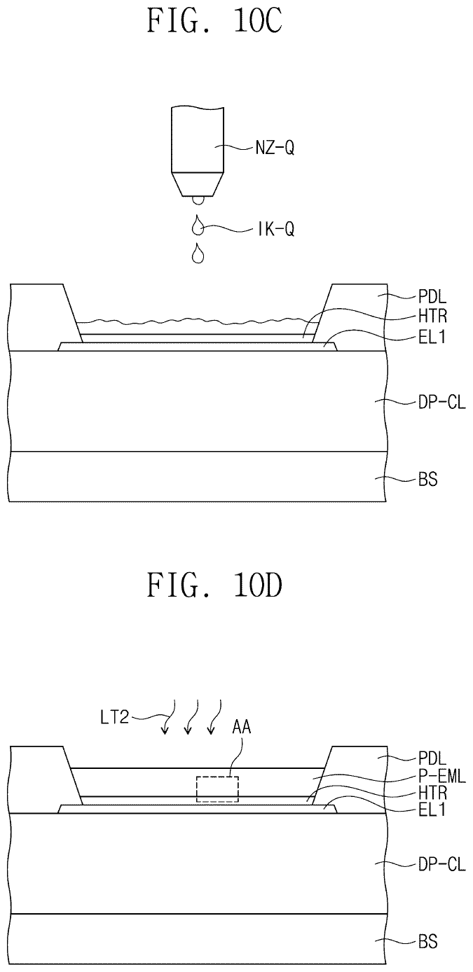

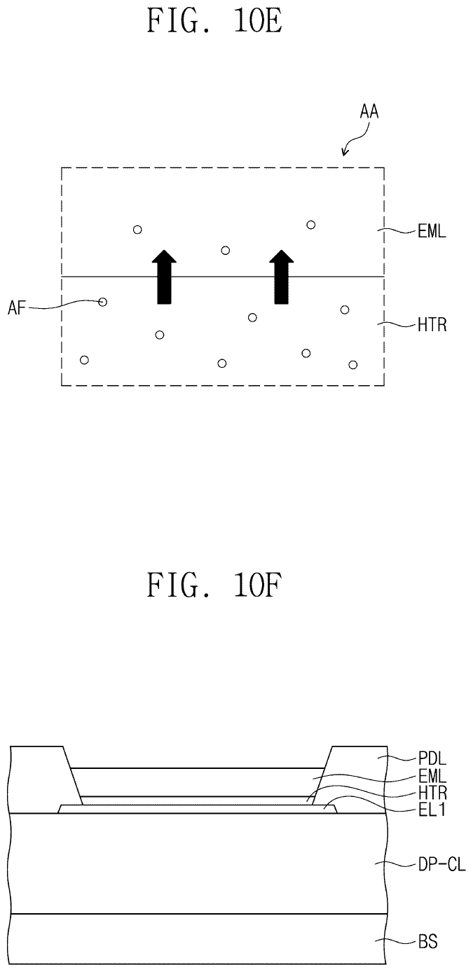

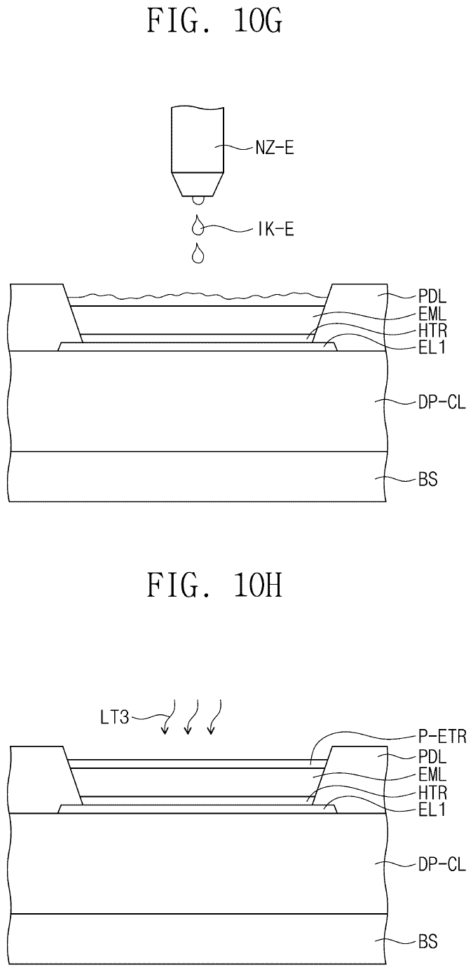

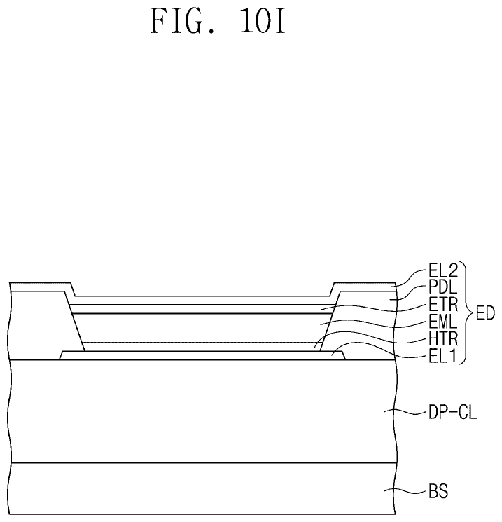

FIG. 10A to FIG. 10I are diagrams schematically illustrating some steps of the method for manufacturing a light-emitting element according to an embodiment.

FIGS. 10A and 10B schematically show the forming of a hole transport region (S100) in the method for manufacturing a light-emitting element according to an embodiment. The forming of a hole transport region (S100) may include forming the hole transport region by providing a mixture including a hole transport material and a first fluoride source on the first electrode EL1.

The forming of the hole transport region (S100) may include forming a preliminary hole transport region P-HTR by providing the mixture IK-H that includes the hole transport material and the first fluoride source onto the first electrode EL1 and drying or performing a heat treatment on the preliminary hole transport region P-HTR. The details for the first fluoride source in FIG. 7A, and FIG. 7B may be similarly applied to the descriptions herein.

Based on the total content 100 wt % of the mixture IK-H, a content of the first fluoride source may be about 10 wt % or less. For example, the content of the first fluoride source may be about 0.01 wt % to about 5 wt %. In a comparative example in which the content of the first fluoride source exceeds about 10 wt %, thin-film durability of the hole transport region may decrease, and functions of the other components included in the hole transport region and the emission layer may deteriorate. In a further comparative example, when the content of the first fluoride source is about 0.01 wt % or less, the first fluoride source may not be sufficient for quantum dot passivation. In an example in which the content of the first fluoride source falls within the above-described range, good thin film characteristics (i.e., thin film characteristics which satisfy target film characteristics) may be maintained, and sufficient quantum dot passivation effects (i.e., quantum dot passivation effects which satisfy a target criteria) may be obtained without negatively affecting the components included in the hole transport region and the emission layer.

A method for applying the mixture IK-H is not particularly limited, methods such as a spin coating method, a cast method, a Langmuir-Blodgett (LB) method, an inkjet printing method, a laser printing method, and a laser induced thermal imaging (LITI) method may be used. For example, the mixture IK-H may be applied on the first electrode EL1 using an inkjet printing method. FIG. 10A illustrates that the mixture IK-H is applied between the pixel-defining film PDL through a first nozzle NZ-H, but embodiments of the present disclosure are not limited thereto.

FIG. 10B is a diagram schematically illustrating drying or performing a heat treatment on the preliminary hole transport region P-HTR in the manufacturing method of a light-emitting element according to an embodiment. The performing a heat treatment on the preliminary hole transport region P-HTR may be providing first heat LT1 to the preliminary hole transport region P-HTR to dry or perform a heat treatment for a predetermined time at a first temperature.

Through the drying or performing a heat treatment of the preliminary hole transport region P-HTR, a solvent included in the mixture IK-H may be removed, and thus a uniform thin layer may be formed. The performing of a heat treatment on the preliminary hole transport region P-HTR may be carried out at the first temperature condition. The first temperature is not particularly limited but may be about 50° C. to about 350° C. However, embodiments of the present disclosure are not limited thereto, and the temperature and time of the drying or heat treatment at the first temperature may be appropriately selected depending on the types, capacity, and the like of the material.

Through the drying or performing heat treatment of the preliminary hole transport region P-HTR, the hole transport region HTR may be formed. The hole transport region HTR formed through the forming of the hole transport region (S100) may include the hole transport material and the first fluoride source.

FIG. 10C to FIG. 10F are views schematically illustrating the forming of the emission layer (S200) in the method for manufacturing a light-emitting element according to an embodiment.

The forming of the emission layer (S200) may include forming a preliminary emission layer by providing, onto the hole transport region HTR, a quantum dot composition IK-Q including a quantum dot and drying or performing a heat treatment on the preliminary emission layer. The quantum dot composition IK-Q may include a quantum dot and a solvent. The descriptions for the first to third quantum dots QD-C1, QD-C2, and QD-C3, described in FIG. 6 and the like, may be similarly applied to the quantum dot included in the quantum dot composition IK-C.

In an embodiment, the quantum dot composition IK-Q may further include a second fluoride source. The quantum dot composition IK-Q may include the quantum dot and the second fluoride source. The descriptions for the first fluoride source, described in FIG. 7A, FIG. 7B and the like, may be similarly applied to the second fluoride source. The second fluoride source included in the quantum dot composition IK-Q may be the same as the first fluoride source included in the mixture IK-H for forming a hole transport region, but is not limited thereto.

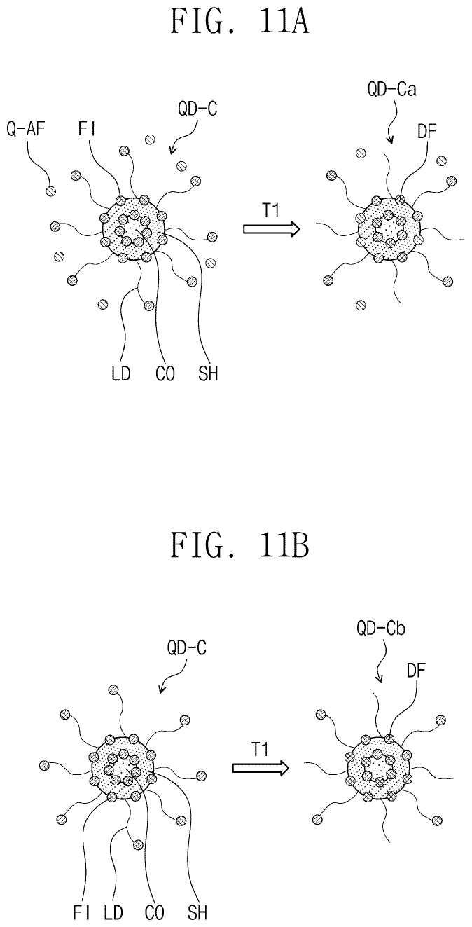

A method for applying the quantum dot composition IK-Q is not particularly limited, methods such as a spin coating method, a cast method, a Langmuir-Blodgett (LB) method, an inkjet printing method, a laser printing method, and a laser induced thermal imaging (LITI) method may be used. For example, the quantum dot composition IK-Q may be applied on the first electrode EL1 using an inkjet printing method. FIG. 11B illustrates that the quantum dot composition IK-Q is applied between the pixel-defining film PDL through a second nozzle NZ-E, but embodiments of the present disclosure are not limited thereto.

FIG. 10C is a diagram schematically illustrating drying or performing a heat treatment on a preliminary emission layer P-EML in the method of manufacturing a light-emitting element according to an embodiment. The performing of a heat treatment on the preliminary emission layer P-EML may be providing second heat LT2 to the preliminary emission layer P-EML and dry or performing a heat treatment for a predetermined time at a second temperature.

Through the drying or performing a heat treatment on the preliminary emission layer P-EML, a solvent included in the quantum dot mixture IK-Q may be removed, and thus a uniform thin layer may be formed. The performing of a heat treatment on the preliminary emission layer P-EML may be carried out at the second temperature condition. The second temperature is not particularly limited but may be about 50° C. to about 350° C. However, embodiments of the present disclosure are not limited thereto, and the temperature and time of drying or performing heat treatment at the second temperature may be appropriately selected depending on the types, capacity, and the like of the material.

The method for manufacturing a light-emitting element according to an embodiment may further include preparing a quantum dot QD-C (see FIG. 7A) prior to the forming of the emission layer (S200). The preparing of the quantum dot may include forming a core, forming a shell, and reacting at least one of a surface of the core or a surface of the shell with hydrofluoric acid. However, embodiments of the present disclosure are not limited thereto, and in the preparing of the quantum dot, the reacting of at least one of the surface of the core or the surface of the shell with the hydrofluoric acid may also be omitted.

In the method for manufacturing a light-emitting element according to an embodiment, the preparing of the quantum dot may include forming a core, reacting a surface of the core with hydrofluoric acid, and forming a shell. The forming of the core, the reacting the surface of the core with hydrofluoric acid, and the forming of the shell may be sequentially performed. That is, the reacting with hydrofluoric acid may be performed after the forming of a core.

The reacting with hydrofluoric acid may include providing a first mixture including the core and the first solvent, and mixing the first mixture and the hydrofluoric acid. The first solvent that supports dispersal of the core may include at least one of hexane, toluene, chloroform, dimethyl sulfoxide, cyclohexylbenzene, hexadecane, or dimethyl formamide. However, embodiments of the present disclosure are not limited thereto.

In the mixing of the first mixture and hydrofluoric acid, the core surface may be reacted with hydrofluoric acid. Hydrofluoric acid may be provided as a solution, dissolved in the solvent. Herein, the solvent is not particularly limited as long as capable of dissolving hydrofluoric acid. For example, water or alcohol may be used as the solvent. Through the mixing of the first mixture and hydrofluoric acid, fluoride ions may be bonded to the surface of the core included in the first mixture. Fluoride ions may be bonded to a positive ion part included to the core.

In the method for manufacturing a light-emitting element according to an embodiment, the preparing of a quantum dot may include forming a core, forming a shell, and reacting a surface of the shell with hydrofluoric acid. The forming of a core, the forming of a shell, and the reacting of a surface of the shell with hydrofluoric acid may be sequentially processed. That is, the reacting with hydrofluoric acid may be performed after the forming of the shell.

Through the forming of the core and the forming of the shell, a first particle having a core/shell structure may be formed. The reacting with hydrofluoric acid may include providing a second mixture including the first particle and a second solvent, and mixing the second mixture and the hydrofluoric acid. The second solvent that supports dispersal of the particle may include at least one of hexane, toluene, chloroform, dimethyl sulfoxide, cyclohexylbenzene, hexadecane, or dimethyl formamide. However, embodiments of the present disclosure are not limited thereto.

In the mixing of the second mixture and hydrofluoric acid, the surface of the shell may react with hydrofluoric acid. Hydrofluoric acid may be provided as a solution, dissolved in the solvent. Herein, the solvent is not particularly limited as long as capable of dissolving hydrofluoric acid. However, for example, water or alcohol may be used as the solvent. Through the mixing of the second mixture and hydrofluoric acid, fluoride ions may bind to the surface of the first particle included in the second mixture. The fluoride ions may bind to a positive ion site included to the shell.

However, embodiments of the present disclosure are not limited thereto, and the reacting with hydrofluoric acid may include reacting each surface of the core and the shell with hydrofluoric acid. Specifically, the reacting with hydrofluoric acid may be performed after each of the forming of a core and the forming of a shell.

In the method for manufacturing a light-emitting element according to an embodiment, the preparing of a quantum dot may include forming a core, reacting a surface of the core with hydrofluoric acid, forming a shell, and reacting a surface of the shell with hydrofluoric acid. The forming of a core, the reacting of a surface of the core with hydrofluoric acid, the forming of a shell, and the reacting of a surface of the shell with hydrofluoric acid may be sequentially processed. For the reacting of the surface of the core with hydrofluoric acid and the reacting of the surface of the core with hydrofluoric acid, the above-described content may be similarly applied. Via the reacting of each surface of the core and the shell with hydrofluoric acid, fluoride ions may bind to each surface of the core and the shell. Fluoride ions may bind to each of positive ion site included in the core, and the positive ion site included in the shell.

In some aspects, when a ligand is used in the preparing of the quantum dot, the ligand may bind to the surface of the prepared quantum dot, and fluoride ions may bind to at least a portion of the ligands. That is, in the quantum dot, the ligand may be present in a state where one end thereof binds to the quantum dot surface, and the other end binds to a fluoride ion. For the ligands, the content described with reference to FIG. 7B and the like may be similarly applied.

The prepared quantum dot through the preparing of the quantum dot according to an embodiment may include fluoride ions binding to the surface of the quantum dot. Therefore, the quantum dot included in the quantum dot composition IK-Q used in the forming of the emission layer (S200) may include the core and the shell, and may be provided in a state where fluoride ions bind to at least one of a surface of the core or a surface of the shell.

Referring to FIGS. 10D and 10E again, in the forming of the emission layer (S200), at least a portion of the first fluoride source AF included in the hole transport region HTR moves to the emission EML. Since the at least a portion of the first fluoride source AF included in the hole transport region HTR moves to the emission EML, a concentration of fluorine in the hole transport region HTR may gradually decrease.

In an embodiment, the fluorine concentration in the hole transport region HTR before the forming of the emission layer (S200) may be defined as a first concentration, the fluorine concentration in the hole transport region HTR after the forming of the emission layer (S200) is defined as a second concentration, and the second concentration may be smaller than the first concentration. Since at least a portion of the first fluoride source AF included in the hole transport region HTR moves to the emission EML in the forming of the emission layer (S200), the concentration of fluorine in the hole transport region HTR may decrease. A change in concentration of fluorine in the hole transport region HTR may be identified using secondary ion mass spectrometry (SIMS) but is not limited thereto.

In the forming of the emission layer (S200), the first fluoride source AF moved from the hole transport region HTR to the emission layer EML may correspond to the above-described second sub fluoride source Q-AF (see FIG. 7B). In the forming of the emission layer (S200), the first fluoride source AF that has not moved to the emission layer EML and remained in the hole transport region HTR may correspond to the above-described first sub fluorine supply H-AF (see FIG. 7B).

The first fluoride source AF moved to the emission layer EML may exist dispersed in the emission layer EML. In some aspects, the first fluoride source AF moved to the emission layer EML from the hole transport region HTR may serve as a quantum dot QD-C passivation factor. Specifically, the first fluoride source AF moved from the hole transport region HTR to the emission layer EML, may recombine to a defect site which is formed by detachment of a fluoride ion (FI, see FIG. 7B) from the quantum dot QD-C when driving the light-emitting element. Therefore, defects formation in the quantum dot QD-C may be suppressed, and thus deterioration in luminous characteristics may be minimized.

In the method for manufacturing a light-emitting element according to an embodiment, FIG. 10G to FIG. 10I are diagrams schematically illustrating forming an electron transport region (S300).

After the forming of the emission layer EML, forming an electron transport region ETR may be carried out on the emission layer EML. In an embodiment, the forming of the electron transport region ETR may be carried out through an inkjet printing method or a spin coating method. In an embodiment, the forming of the electron transport region ETR may include forming a preliminary electron transport region P-ETR by providing, onto the emission layer EML, an electron transport composition IK-E and performing a heat treatment on the preliminary electron transport region P-ETR.

The electron transport composition may include an inorganic particle MP (FIG. 8) and a solvent. For the inorganic particle MP (FIG. 8), the content described in FIG. 8 may be similarly applied.

A method for applying the electron transport composition IK-E is not particularly limited, and methods such as a spin coating method, a cast method, a Langmuir-Blodgett (LB) method, an inkjet printing method, a laser printing method, and a laser induced thermal imaging (LITI) method may be used. For example, the electron transport composition IK-E may be applied on the emission layer EML using an inkjet printing method. FIG. 10G illustrates that the electron transport composition IK-E is applied between the pixel-defining film PDL through a third nozzle NZ-E, but embodiments of the present disclosure are not limited thereto.

FIG. 10H is a diagram schematically illustrating drying or performing a heat treatment on the preliminary electron transport region P-ETR in the method for manufacturing a light-emitting element according to an embodiment. The drying or performing a heat treatment on the preliminary electron transport region P-ETR may be providing third heat LT3 to the preliminary electron transport region P-ETR to dry or perform a heat treatment for a predetermined time at a third temperature.

Through the drying or performing a heat treatment on the preliminary electron transport region P-ETR, a solvent included in the electron transport composition IK-E may be removed, and thus a uniform thin layer may be formed. The the performing a heat treatment of the preliminary electron transport region P-ETR may be performed at the third temperature condition. The third temperature is not particularly limited but may be about 50° C. to about 350° C. However, embodiments of the present disclosure are not limited thereto, and the temperature and time of drying or heat treatment at the third temperature may be appropriately selected depending on the types, capacity, and the like of the material.

In the method for manufacturing a light-emitting element according to an embodiment, when the electron transport region ETR is formed using the electron transport composition IK-E, a light-emitting element ED having a structure illustrated in FIG. 8 may be formed.

However, embodiments of the present disclosure are not limited thereto, and the forming of the electron transport region ETR may be depositing an electron transport material on the emission layer EML. In this case, through the forming of the electron transport region ETR, the light-emitting element ED illustrated in FIG. 7A may be formed. The electron transport material for forming the electron transport region ETR may be the material for the electron transport region ETR described in FIG. 7A.

In FIG. 10A to FIG. 10H, the hole transport region HTR and the electron transport region ETR are each illustrated to be provided between the pixel-defining film PDL, but embodiments of the present disclosure are not limited thereto. The hole transport region HTR and the electron transport region ETR may be each provided as a common layer so as to overlap the pixel-defining film PDL.

Referring to FIG. 10I, after the forming of the electron transport region ETR, forming of the second electrode EL2 may be carried out. The second electrode EL2 is formed on the electron transport region ETR, and thus the light-emitting element ED, in which the first electrode EL1, the hole transport region HTR, the emission layer EML, the electron transport region ETR, and the second electrode EL2 are sequentially stacked, may be formed.

In the quantum dot, since charge carriers are trapped influenced by surface dangling bonds or the like, luminescence efficiency may decrease. The presence of the dangling bonds and the like within the quantum dot causes non-radiative recombination, which may cause a decrease in luminous efficiency. As a passivation method of the surface defect of the quantum dot, a method of treating by hydrofluoric acid (HF) on the surface during synthesis of the quantum dot may be used. The hydrofluoric acid (HF)-treated quantum dot may be passivated by fluoride ions, and thus include fluoride ions bonded to the surface. The hydrofluoric acid binds to the surface of the quantum dot, and thus the number of surface trap states caused by the dangling bonds and the like may decrease. However, the fluoride ion provided through the surface treatment may be detached from the quantum dot and lost during the synthesis of the quantum dot, the manufacturing process of a light-emitting element, or the driving of the light-emitting element. Therefore, there is a limitation to reduce the number of surface defects in the quantum dot to a certain degree by using only the hydrofluoric acid-treatment method.

According to an embodiment of the inventive concept, the method for manufacturing a light-emitting element may include forming the hole transport region by providing the mixture including the hole transport material and the first fluoride source. In the forming of the emission layer, the first fluoride source moves from the hole transport region to the emission layer, and thus passivation factors that are capable of substituting for lost fluoride ions from the quantum dot QD-C may be provided. That is, the first fluoride source provided from the hole transport region may recombine the site of defect formed by the detachment of the fluoride ions. Therefore, the defect formation within the quantum dot QD-C may be suppressed, and thus deterioration in luminous characteristics may be minimized.

FIG. 11A is a diagram schematically illustrating changes over time of a quantum dot included in a light-emitting element according to an example. FIG. 111B is a diagram schematically illustrating changes over time of a quantum dot included in a light-emitting element according to a comparative example. FIG. 11A and FIG. 111B show changes in states of the quantum dot included in the light-emitting element before driving and after driving for a predetermined time.

It can be confirmed that the light-emitting elements according an example and a comparative example have the structure of the light-emitting element illustrated in FIG. 7A. Each of the light-emitting elements according to an example and a comparative example include an emission layer including a quantum dot QD-C. The quantum dot QD-C included in the light-emitting elements according to an example and a comparative example is provided in a state where fluoride ions (FI) bind to the surface of the quantum dot QD-C. That is, the quantum dot QD-C included in the light-emitting elements according to an example and a comparative example is hydrofluoric acid-treated during the manufacturing of the quantum dot, and includes fluoride ions (FI).

The light-emitting element according to an example include the first fluoride sources Q-AF and H-AF (see FIG. 7A) in each of the emission layer and the hole transport region. As illustrated in FIG. 11A, the light-emitting element according to an example include the first fluoride source Q-AF in the emission layer. The first fluoride source Q-AF included in the emission layer may exist dispersed in the emission layer. The first fluoride source Q-AF may correspond to a fluoride source moved from the hole transport region to the emission layer during the forming of the hole transport region.

The light-emitting element according to a comparative example is the same as the light-emitting element according to an example except that each of the emission layer and the hole transport region includes no first fluoride sources Q-AF and H-AF (see FIG. 7A). That is, the light-emitting element according to a comparative example corresponds to a light-emitting element in which the first fluoride source is not provided during the forming of the hole transport region, and thus, unlike the light-emitting element according to an example, includes no first fluoride source Q-AF moved from the hole transport region to the emission layer.

Referring to FIG. 11A and FIG. 11B, the light-emitting elements according to an example and a comparative example may include a quantum dot QD-C. The quantum dot QD-C may include a core CO and a shell SH covering the core CO. In some aspects, the quantum dot QD-C may further include a ligand LD that recombines the shell SH surface. The quantum dot QD-C may include fluoride ions (FI) bonded to the surface of the quantum dot QD-C. The fluoride ion (FI) may be present in a state where a bond with at least one of the core CO or the shell SH is formed. In some aspects, the fluoride ion (FI) may also be present in a state of binding to the ligand LD. The state of the quantum dot QD-C may be changed after the driving of the light-emitting element for a predetermined time, as compared to the light-emitting element before the driving.

Referring to FIG. 11A and FIG. 11B, after the driving of the light-emitting element for a predetermined time (T1), the quantum dots QD-C included in the light-emitting elements according to an example and a comparative example may be changed into Example Quantum dot QD-Ca and Comparative Example Quantum dot QD-Cb, respectively. Example Quantum dot QD-Ca and Comparative Example Quantum dot QD-Cb may each have a state where some fluoride ions bonded to the surface are detached and form a defect DF. During the driving of the light-emitting element, some fluoride ions (FI) bonded to the initial quantum dot QD-C may be detached. In an example in which the fluoride ions (FI) are detached, the defects DF are formed on the surface of the quantum dot, and thus luminous efficiency of the quantum dot may decrease. Alternatively, the charge carriers are trapped on the surface of the quantum dot, which may cause a decrease in electrical characteristics.

The light-emitting element according to an embodiment includes an emission layer and a hole transport region, each including a fluoride source, and thus passivation effects on a quantum dot included in the emission layer may be improved.

The electronic apparatus according to an embodiment includes the light-emitting element including a quantum dot which exhibits improved emission characteristics, thereby capable of illustrating excellent display quality.

The method for manufacturing a light-emitting element according to an embodiment, in the forming of the emission layer, enables the fluoride source to move from the hole transport region to the emission layer, and thus passivation effects on the quantum dot included in the emission layer may be improved. Therefore, a light-emitting element relatively having high luminous efficiency and improved lifespan characteristics compared to other light-emitting elements may be provided using the methods described herein.

Hitherto, although the embodiments of the inventive concept have been described with reference to preferable embodiments, and those skilled in the art or having ordinary knowledge of the art will understand that various modifications and changes can be made without departing from the technical idea or features of the inventive concept as described later in the claims, which will be described hereinafter. Accordingly, the technical scope of the inventive concept is not limited to what is set forth in the detailed description of the specification, but should be defined by the claims.

What is claimed is:

1. A method for manufacturing a light-emitting element, the method comprising:
forming a hole transport region by providing, on a first electrode, a mixture comprising a hole transport material and a first fluoride source that comprises fluorine;
forming an emission layer comprising a quantum dot on the hole transport region;
forming an electron transport region on the emission layer; and
forming a second electrode on the electron transport region,
wherein, in the forming of the emission layer, at least a portion of the first fluoride source comprised in the hole transport region moves to the emission layer.

2. The method for manufacturing a light-emitting element of claim 1, wherein:
a concentration of fluorine in the hole transport region before the forming of the emission layer is defined as a first concentration,
a concentration of fluorine in the hole transport region after the forming of the emission layer is defined as a second concentration, and
the second concentration is smaller than the first concentration.

3. The method for manufacturing a light-emitting element of claim 1, wherein the quantum dot comprises:
a core;
a shell covering the core; and
fluorine ions bonded to at least one of:
a surface of the core; or
a surface of the shell.

4. The method for manufacturing a light-emitting element of claim 3, the method further comprising preparing a quantum dot prior to the forming of the emission layer,
wherein the preparing of the quantum dot comprises:
forming the core;
forming the shell; and
reacting the at least one of the surface of the core or the surface of the shell with fluorine.

5. The method for manufacturing a light-emitting element of claim 1, wherein the forming of the hole transport region is carried out through an inkjet process.

6. The method for manufacturing a light-emitting element of claim 1, wherein the forming of the hole transport region comprises:
forming a preliminary hole transport region by providing, on the first electrode, the mixture that comprises the hole transport material and the first fluoride source; and
drying or performing a heat treatment on the preliminary hole transport region.

7. The method for manufacturing a light-emitting element of claim 1, wherein the forming of the emission layer is carried out through an inkjet process.

8. The method for manufacturing a light-emitting element of claim 1, wherein, the forming of an emission layer comprises:
forming a preliminary emission layer by providing a quantum dot composition comprising the quantum dot onto the hole transport region; and
drying or performing a heat treatment on the preliminary emission layer.

9. The method for manufacturing a light-emitting element of claim 8, wherein the quantum dot composition further comprises a second fluoride source.

10. The method for manufacturing a light-emitting element of claim 1, wherein the forming of the electron transport region comprises:
forming a preliminary electron transport region by providing an electron transport composition comprising an electron transport material on the emission layer; and
drying or performing a heat treatment on the preliminary electron transport region.

11. The method for manufacturing a light-emitting element of claim 1, wherein the electron transport material comprises a metal oxide.

12. A light-emitting element comprising:
a first electrode;
a second electrode disposed on the first electrode;
an emission layer disposed between the first electrode and the second electrode and comprising a quantum dot, and
a hole transport region disposed between the first electrode and the emission layer,
wherein the emission layer and the hole transport region each comprise a first fluoride source comprising fluorine.

13. The light-emitting element of claim 12, wherein:
the hole transport region comprises:
a hole injection layer disposed on the first electrode; and
a hole transport layer disposed on the hole injection layer and contacting the emission layer, and
the hole transport layer comprises the first fluoride source.

14. The light-emitting element of claim 12, wherein the quantum dot comprises:
a core, and
a shell covering the core.

15. The light-emitting element of claim 14, wherein the quantum dot further comprises fluorine ions bonded to at least one of a surface of the core or a surface of the shell.

16. The light-emitting element of claim 14, wherein, the quantum dot further comprises a ligand bonded to at least one of a surface of the core or a surface of the shell.

17. The light-emitting element of claim 12, further comprising an electron transport region disposed between the second electrode and the emission layer and comprising a metal oxide.

18. An electronic apparatus comprising:
a display module comprising:
a display panel; and
an input sensor disposed on the display panel; and
a power source module which supplies power to the display module,
wherein:
the display panel comprises:
a circuit layer; and
a display element layer disposed on the circuit layer and comprising a pixel-defining film in which a light-emitting element and a pixel opening are defined, and
the light-emitting element comprises:
a first electrode;
a second electrode disposed on the first electrode;
an emission layer disposed between the first electrode and the second electrode and comprising a quantum dot; and
a hole transport region disposed between the first electrode and the emission layer, wherein each of the emission layer and the hole transport region comprises a first fluoride source comprising fluorine.

19. The electronic apparatus of claim 18, wherein:
a fluorine concentration in the emission layer, measured before applying a voltage to the light-emitting element, is set as a reference concentration, and
a concentration of fluorine in the emission layer, after applying a voltage to the light-emitting element, gradually increases from the reference concentration.

20. The electronic apparatus of claim 18, wherein:
the light-emitting element comprises:
a first light-emitting element comprising a first emission layer that is which emits blue light;
a second light-emitting element comprising a second emission layer that is which emits green light; and
a third light-emitting element comprising a third emission layer that is which emits red light, and
at least one among the first emission layer, the second emission layer, or the third emission layer comprises the quantum dot and the first fluoride source.
